(19) United States
(12) Patent Application Publication
(10) Pub. No.: US 2026/0123112 A1
(43) Pub. Date: Apr. 30, 2026

(54) SEMICONDUCTOR LIGHT-EMITTING ELEMENT AND DISPLAY DEVICE

(71) Applicant: LG ELECTRONICS INC., Seoul (KR)

(72) Inventors: Wonyong LEE, Seoul (KR); Hyunggu KIM, Seoul (KR); Sukkoo JUNG, Seoul (KR); Yangmi KWON, Seoul (KR)

(73) Assignee: LG ELECTRONICS INC., Seoul (KR)

(21) Appl. No.: 19/123,668

(22) PCT Filed: Oct. 27, 2022
(86) PCT No.: PCT/KR2022/016567

§ 371 Date: Apr. 23, 2025

(51) Int. Cl. H10H 20/832; H10H 20/819; H10H 20/831; H10H 20/84; H10H 29/49

(52) U.S. Cl. CPC H10H 20/835; H10H 20/819; H10H 20/8312; H10H 20/84; H10H 29/49

(57) ABSTRACT

The semiconductor light-emitting element may include a light-emitting layer, a passivation layer surrounding a lateral part of the light-emitting layer, a first electrode under the light-emitting layer, and a second electrode on the light-emitting layer. The light-emitting layer may have a first region and a second region surrounding the first region. A lower surface of the first region of the light-emitting layer may have a recess. The first electrode may include an ohmic contact layer in the recess, a reflective layer under the second region of the light-emitting layer, and a magnetic layer under the reflective layer. An area of the reflective layer may exceed 50% of an area of a lower side of the light-emitting layer.

### TECHNICAL FIELD

The embodiment relates to a semiconductor light-emitting element and a display device.

### BACKGROUND ART

A large-area display include a liquid crystal display (LCDs), an OLED display, and a micro-LED display.

A micro-LED display is a display that uses micro-LEDs, which are semiconductor light-emitting elements having a diameter or cross-sectional area of 100 μm or less, as display elements.

Since the micro-LED display uses the micro-LEDs, the semiconductor light-emitting elements, as the display elements, it has excellent performance in many characteristics such as contrast ratio, response speed, color reproducibility, viewing angle, brightness, resolution, lifespan, luminous efficiency, or luminance.

In particular, a micro-LED display has the advantage of being able to freely adjust the size or resolution by separating and combining the screen in a modular manner, and the advantage of being able to implement a flexible display.

However, since a large micro-LED display requires millions or more micro-LEDs, there is a technical problem that makes it difficult to quickly and accurately transfer micro-LEDs to the display panel.

Recently developed transfer technologies include the pick and place process, the laser lift-off method, and the self-assembly method.

Among these, the self-assembly method is a method in which semiconductor light-emitting elements find their assembly positions within a fluid, which is advantageous for implementing a large-screen display device.

However, research on the technology for manufacturing displays through self-assembly of micro-LEDs is still insufficient.

In particular, in the case of rapidly transferring millions or more semiconductor light-emitting elements to a large display in a conventional technology, the transfer speed can be improved, but the transfer error rate may increase, which causes a technical problem in that the transfer yield decreases.

In the related technology, a self-assembly transfer process using dielectrophoresis (DEP) is being attempted, but there is a problem that the self-assembly rate is low due to the non-uniformity of the DEP force.

On the other hand, a semiconductor light-emitting elements such as micro-LEDs has a problem of low luminance due to their small size. In particular, there is a problem that the luminance of a red semiconductor light-emitting element is lower than that of a blue semiconductor light-emitting element or a green semiconductor light-emitting element due to material characteristics. Therefore, the development of technology that may improve the luminance of the semiconductor light-emitting element is urgent.

According to a non-public internal technology, a method of forming an ohmic contact layer over the entire region of a lower surface of a semiconductor light-emitting element was proposed to increase the light efficiency (or light luminance). However, there is a problem that the ohmic contact layer acts as a light absorption layer during heat treatment to form the ohmic contact layer, which reduces the light efficiency.

On the other hand, in order for the semiconductor light-emitting element to immediately respond to the magnet used in the self-assembly method, the magnetization force of the semiconductor light-emitting element must be large. However, due to the very small size of the semiconductor light-emitting element, there is a limit to increasing the magnetization force, so that there is a problem that the assembly rate is reduced during self-assembly.

### DISCLOSURE

### Technical Problem

Another object of the embodiment is to provide a semiconductor light-emitting element and a display device capable of improving light efficiency and light luminance.

In addition, another object of the embodiment is to provide a semiconductor light-emitting element and a display device capable of improving the assembly rate.

The technical problems of the embodiments are not limited to those described in this item and include those that may be understood through the description of the invention.

### Technical Solution

In order to achieve the above or other objects, according to one aspect of the embodiment, a semiconductor light-emitting element comprises: a light-emitting layer; a passivation layer surrounding a lateral part of the light-emitting layer; a first electrode under the light-emitting layer; and a second electrode on the light-emitting layer; wherein the light-emitting layer has a first region and a second region surrounding the first region and a lower surface of the first region of the light-emitting layer has a recess, wherein the first electrode comprises an ohmic contact layer in the recess; a reflective layer under the second region of the light-emitting layer; and a magnetic layer under the reflective layer, and wherein an area of the reflective layer exceeds 50% of an area of the lower side of the light-emitting layer.

An area of the ohmic contact layer may be 5% to 50% of the area of the lower side of the light-emitting layer.

The reflective layer may be disposed under the ohmic contact layer. The reflective layer may comprise a protrusion surrounding the ohmic contact layer in the recess.

A lower surface of the ohmic contact layer and a lower surface of the second region of the light-emitting layer may be positioned on a same horizontal line.

A lower surface of the ohmic contact layer may be positioned higher than a lower surface of the second region of the light-emitting layer. The magnetic layer may have a second recess corresponding to the recess. The magnetic layer is disposed under the reflective layer and a lower surface of the magnetic layer may have a straight plane.

A lower surface of the ohmic contact layer may be positioned lower than a lower surface of the second region of the light-emitting layer. The magnetic layer may be disposed under the reflective layer and a lower surface of the magnetic layer may have a straight plane.

The recess may have a depth of at least ½ of a thickness of a first conductivity type semiconductor layer of the light-emitting layer. The recess may have a bottom surface and a slope surface, the ohmic contact layer may be disposed on the bottom surface, and the reflective layer may be disposed on the slope surface.

The semiconductor light-emitting element may comprise an unevenness on a surface of the recess and the ohmic contact layer may be disposed on the unevenness.

The first electrode may comprise a contact electrode under the magnetic layer. At least one of the reflective layer, the magnetic layer, or the contact electrode may be disposed on a lateral part of the light-emitting layer.

According to another aspect of the embodiment, a display device, comprising: a backplane substrate; a plurality of semiconductor light-emitting elements configured to emit light of different colors on the backplane substrate; a connecting electrode on each lateral part of the plurality of semiconductor light-emitting elements; and an electrode wiring on each upper side of the plurality of semiconductor light-emitting elements, wherein at least one or more of the plurality of semiconductor light-emitting elements comprises: a light-emitting layer; a passivation layer configured to surround a lateral part of the light-emitting layer; a first electrode under the light-emitting layer; and a second electrode over the light-emitting layer, wherein the light-emitting layer has a first region and a second region configured to surround the first region and a lower surface of the first region of the light-emitting layer has a recess, and wherein the first electrode comprises: an ohmic contact layer in the recess; a reflective layer under the second region of the light-emitting layer; and a magnetic layer under the reflective layer.

### Advantageous Effects

In the embodiment, in the first electrode disposed on the lower side of the light-emitting layer, the area of the ohmic contact layer can be minimized and the area of the reflective layer can be maximized. That is, as illustrated in FIGS. 7 to 9, the ohmic contact layer 154-1 of the first electrode 154 may be disposed under a first region 150a of the light-emitting layer 151 to 153, and the reflective layer 154-2 may be disposed under a second region 150b of the light-emitting layer 151 to 153 surrounding the first region 150a. At this time, the area A2 of the reflective layer 154-2 may exceed 50% of the area of the lower side of the light-emitting layer 151 to 153. Accordingly, the light reflectivity by the reflective layer 154-2 can be increased, so that the light efficiency and luminance can be improved.

In addition, since the magnetic layer 154-3 is disposed under the reflective layer 154-2, the response speed of the semiconductor light-emitting element 150A to the magnet can be increased by the magnetic layer 154-3 during self-assembly, thereby improving the assembly rate.

As illustrated in FIGS. 19 and 20, the depth d2 of the recess 158 formed on the lower surface of the first region 150a of the light-emitting layer 151 to 153 may be greater than the total of the thickness of the ohmic contact layer 154-1, the thickness of the reflective layer 154-2, and the thickness of the magnetic layer 154-3, so that a recess 154-3a corresponding to the recess 158 may be formed in the magnetic layer 154-3. A semiconductor light-emitting element 150B having such a recess 154-3 may be disposed on a substrate 310 as a red semiconductor light-emitting element 150-1, and a display device 301 may be manufactured through electrical connection by a post-process. At this time, the second insulating layer 335 may be disposed not only between the lower side of the red semiconductor light-emitting element 150-1 and the first insulating layer 330, but also in the corresponding recess 154-3a, so that the contact area between the red semiconductor light-emitting element 150-1 and the second insulating layer 335 can be expanded, and thus the fixation of the red semiconductor light-emitting element 150-1 can be strengthened.

Meanwhile, as illustrated in FIG. 25 and FIG. 28, since the depth d4 and d5 of the recess 158 is more than half the thickness of the first conductivity type semiconductor layer 151, the ohmic contact layer 154-1 disposed in the recess 158 may be positioned as close as possible to the active layer 152. Accordingly, since the shortest current paths are formed between the second electrode 155 and the ohmic contact layer 154-1 of the first electrode 154, more light may be generated by the driving current flowing through the shortest current paths, so that the light efficiency and luminance can be improved.

In addition, as illustrated in FIG. 29, an unevenness 159 may be formed on the inner surface of the recess 158, and an ohmic contact layer 154-1 may be disposed on the unevenness 159. In this instance, light traveling from the active layer 152 toward the ohmic contact layer 154-1 may be diffusely reflected or scattered by the unevenness 159 before being absorbed by the ohmic contact layer 154-1, so that light efficiency or luminance can be improved.

In addition, as illustrated in FIG. 30, since at least one of the reflective layer 154-2, the magnetic layer 154-3, or the contact electrode 154-4 is disposed on the lateral part of the light-emitting layer 151 to 153, the contact area with the connecting electrode placed on the side of the semiconductor light-emitting element 150H can be expanded during the manufacture of the display device, so that the electrical characteristics can be improved. Accordingly, light efficiency and luminance can be improved, and low-voltage operation can be enabled, reducing power consumption.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 illustrates a living room of a house in which a display device according to an embodiment is disposed.

FIG. 2 is a block diagram schematically showing a display device according to an embodiment.

FIG. 3 is a circuit diagram showing an example of a pixel of FIG. 2.

FIG. 4 is an enlarged view of a first panel region in the display device of FIG. 1.

FIG. 5 is an enlarged view of a region A2 of FIG. 4.

FIG. 6 is a drawing showing an example in which a light-emitting element according to an embodiment is assembled on a substrate by a self-assembly method.

FIG. 7 is a cross-sectional view illustrating a semiconductor light-emitting element according to a first embodiment.

FIG. 8 is a plan view illustrating a semiconductor light-emitting element according to the first embodiment.

FIG. 9 is a bottom view illustrating a semiconductor light-emitting element according to the first embodiment.

FIG. 10 is a bottom view illustrating a first conductivity type semiconductor layer of a semiconductor light-emitting element according to the first embodiment.

FIG. 11 is an enlarged view illustrating a C region in a semiconductor light-emitting element according to the embodiment of FIG. 7.

FIG. 12A illustrates light reflectance in a semiconductor light-emitting element according to a comparative example.

FIG. 12B shows reflectance before and after heat treatment.

FIG. 13 illustrates light reflectance in a semiconductor light-emitting element according to the first embodiment.

FIG. 14 shows light efficiency in a comparative example and the embodiment.

FIG. 15 shows light luminance in a comparative example and the embodiment.

FIG. 16 is a plan view illustrating a display device according to a first embodiment.

FIG. 17 is a cross-sectional view taken along the line D1-D2 in the display device according to the first embodiment of FIG. 16.

FIG. 18 is a cross-sectional view illustrating a backplane substrate of an embodiment.

FIG. 19 is a cross-sectional view illustrating a semiconductor light-emitting element according to a second embodiment.

FIG. 20 is a cross-sectional view illustrating a display device according to the second embodiment.

FIG. 21 is a cross-sectional view illustrating a semiconductor light-emitting element according to a third embodiment.

FIG. 22 is a cross-sectional view illustrating a semiconductor light-emitting element according to a fourth embodiment.

FIG. 23 is a cross-sectional view illustrating each of a semiconductor light-emitting element for lighting and a semiconductor light-emitting element for display according to the embodiment.

FIG. 24 is a bottom view illustrating each of a semiconductor light-emitting element for lighting and a semiconductor light-emitting element for display according to the embodiment.

FIG. 25 is a cross-sectional view illustrating a semiconductor light-emitting element according to a fifth embodiment.

FIG. 26 shows light reflection and current flow in a semiconductor light-emitting element according to the fifth embodiment.

FIG. 27 is a cross-sectional view illustrating a display device according to a third embodiment.

FIG. 28 is a cross-sectional view illustrating a semiconductor light-emitting element according to a sixth embodiment.

FIG. 29 is a cross-sectional view illustrating a semiconductor light-emitting element according to a seventh embodiment.

FIG. 30 is a cross-sectional view illustrating a semiconductor light-emitting element according to an eighth embodiment.

FIG. 31 is a cross-sectional view illustrating a semiconductor light-emitting element according to a ninth embodiment.

FIG. 32 is a bottom view illustrating a semiconductor light-emitting element according to the ninth embodiment.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

The display device described in this specification may comprise a TV, a signage, a mobile terminal such as a mobile phone or a smart phone, a computer display such as a laptop or a desktop, a head-up display (HUD) for an automobile, a backlight unit for a display, a display for VR, AR or mixed reality (MR), a light source, etc. However, the configuration according to the embodiment described in this specification may be equally applied to a device capable of displaying, even if it is a new product type developed in the future.

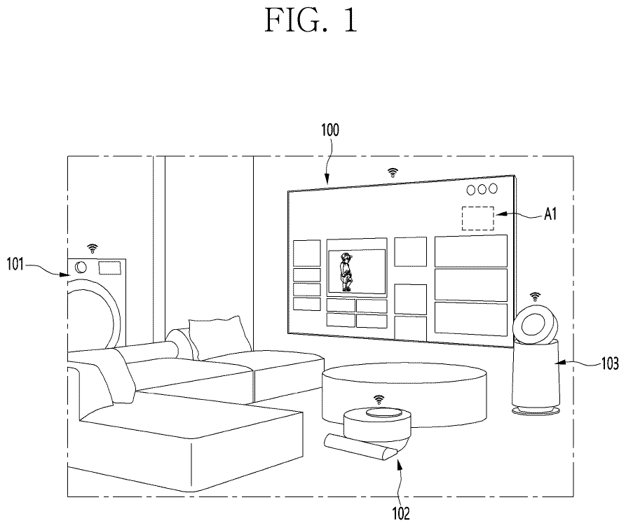

FIG. 1 illustrates a living room of a house in which a display device according to an embodiment is disposed.

Referring to FIG. 1, the display device 100 according to the embodiment may display the status of various electronic products such as a washing machine 101, a robot vacuum cleaner 102, an air purifier 103, etc., and may communicate with each electronic product based on IoT and control each electronic product based on user setting data.

The display device 100 according to the embodiment may comprise a flexible display manufactured on a thin and flexible substrate. The flexible display may be bent or rolled like paper while maintaining the characteristics of a conventional flat display.

In a flexible display, visual information may be implemented by independently controlling the light emission of unit pixels disposed in a matrix form. A unit pixel means a minimum unit for implementing one color. The unit pixel of the flexible display may be implemented by a light-emitting element. In an embodiment, the light-emitting element may be a micro-LED or a nano-LED, but is not limited thereto.

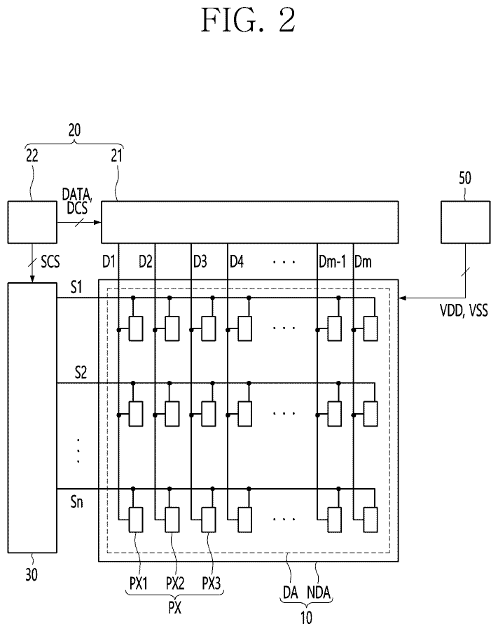

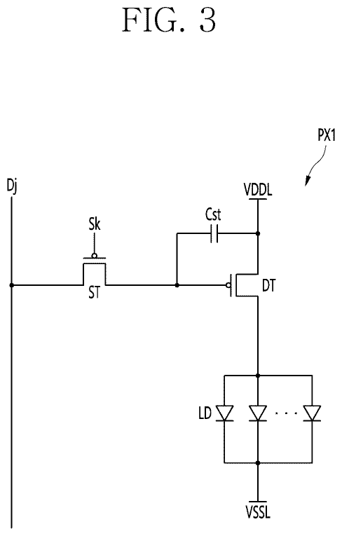

FIG. 2 is a block diagram schematically showing a display device according to an embodiment, and FIG. 3 is a circuit diagram showing an example of a pixel of FIG. 2.

Referring to FIG. 2 and FIG. 3, a display device according to an embodiment may comprise a display panel 10, a driving circuit 20, a scan driving unit 30, and a power supply circuit 50.

The display device 100 of the embodiment may drive a light-emitting element in an active matrix (AM) manner or a passive matrix (PM) manner.

The driving circuit 20 may comprise a data driving unit 21 and a timing control unit 22.

The display panel 10 may be formed in a rectangular shape, but is not limited thereto. That is, the display panel 10 may be formed in a circular or oval shape. At least one side of the display panel 10 may be formed to be bent at a predetermined curvature.

The display panel may comprise a display region DA. The display region DA is a region where pixels PX are formed to display an image. The display panel may comprise a non-display region NDA. The non-display region NDA may be a region excluding the display region DA.

As an example, the display region DA and the non-display region NDA may be defined on the same surface. For example, the non-display region NDA may surround the display region DA on the same surface together with the display region DA, but is not limited thereto.

As another example, although not illustrated in the drawing, the display region DA and the non-display region NDA may be defined on different surfaces. For example, the display region DA may be defined on the upper surface of the substrate, and the non-display region NDA may be defined on the lower surface of the substrate. For example, the non-display region NDA may be defined on the entire region or a part of the lower surface of the substrate.

Meanwhile, although the drawing illustrates that the display region DA and the non-display region NDA are divided, the display region DA and the non-display region NDA may not be divided. In other words, only the display region DA may exist on the upper surface of the substrate, and the non-display region NDA may not exist. In other words, the entire region of the upper surface of the substrate may be the display region DA where the image is displayed, and a bezel region, which is the non-display region NDA, may not exist.

The display panel 10 may comprise data lines (D1 to Dm, where m is an integer greater than or equal to 2), scan lines (S1 to Sn, where n is an integer greater than or equal to 2) intersecting the data lines D1 to Dm, a high-potential voltage line VDDL supplied with a high-potential voltage VDD, a low-potential voltage line VSSL supplied with a low-potential voltage VSS, and pixels PX connected to the data lines D1 to Dm and the scan lines S1 to Sn.

Each of the pixels PX may comprise a first subpixel PX1, a second subpixel PX2, and a third subpixel PX3. The first subpixel PX1 may emit a first color light of a first main wavelength, the second subpixel PX2 may emit a second color light of a second main wavelength, and the third subpixel PX3 may emit a third color light of a third main wavelength. The first color light may be red light, the second color light may be green light, and the third color light may be blue light, but is not limited thereto. In addition, although FIG. 2 exemplifies that each of the pixels PX comprises three subpixels, the present invention is not limited thereto. That is, each of the pixels PX may comprise four or more subpixels.

Each of the first subpixel PX1, the second subpixel PX2, and the third subpixel PX3 may be connected to at least one of the data lines D1 to Dm, at least one of the scan lines S1 to Sn, and a high-potential voltage line VDDL. The first subpixel PX1 may comprise light-emitting elements LD, a plurality of transistors for supplying current to the light-emitting elements LD, and at least one capacitor Cst, as illustrated in FIG. 3.

Although not illustrated in the drawing, each of the first subpixel PX1, the second subpixel PX2, and the third subpixel PX3 may comprise only one light-emitting element LD and at least one capacitor Cst.

Each of the light-emitting elements LD may be a semiconductor light-emitting diode comprising a first electrode, a plurality of conductivity type semiconductor layers, and a second electrode. Here, the first electrode may be an anode electrode, and the second electrode may be a cathode electrode, but is not limited thereto.

The light-emitting element LD may be one of a lateral-type light-emitting element, a flip-chip type light-emitting element, and a vertical-type light-emitting element.

The plurality of transistors may comprise a driving transistor DT for supplying current to the light-emitting elements LD, and a scan transistor ST for supplying a data voltage to the gate electrode of the driving transistor DT, as illustrated in FIG. 3. The driving transistor DT may comprise a gate electrode connected to the source electrode of the scan transistor ST, a source electrode connected to a high-potential voltage line VDDL to which a high-potential voltage VDD is applied, and a drain electrode connected to the first electrodes of the light-emitting elements LD. The scan transistor ST may comprise a gate electrode connected to a scan line (Sk, where k is an integer satisfying 1≤k≤n), a source electrode connected to the gate electrode of the driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges a difference value between the gate voltage and the source voltage of the driving transistor DT.

The driving transistor DT and the scan transistor ST may be formed as thin film transistors. In addition, although FIG. 3 mainly describes the driving transistor DT and the scan transistor ST as formed as a P-type metal oxide semiconductor field effect transistor (MOSFET), the present invention is not limited thereto. The driving transistor DT and the scan transistor ST may also be formed as an N-type MOSFET. In this instance, the positions of the source electrode and the drain electrode of each of the driving transistor DT and the scan transistor ST may be changed.

In addition, FIG. 3 exemplifies the case where the first subpixel PX1, the second subpixel PX2, and the third subpixel PX3 each comprise 2T1C (2 Transistor-1 capacitor) having one driving transistor DT, one scan transistor ST, and one capacitor Cst, the present invention is not limited thereto. The first subpixel PX1, the second subpixel PX2, and the third subpixel PX3 each may comprise a plurality of scan transistors ST and a plurality of capacitors Cst.

The second subpixel PX2 and the third subpixel PX3 may be expressed by substantially the same circuit diagram as the first subpixel PX1, so that a detailed description thereof is omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts the digital video data DATA into analog data voltages according to the source control signal DCS and supplies the converted data to the data lines D1 to Dm of the display panel 10.

The timing control unit 22 receives digital video data DATA and timing signals from a host system. The host system may be an application processor of a smartphone or tablet PC, a monitor, a system-on-chip of a TV, etc.

The timing control unit 22 generates control signals for controlling the operation timing of the data driving unit 21 and the scan driving unit 30. The control signals may comprise a source control signal DCS for controlling the operation timing of the data driving unit 21 and a scan control signal SCS for controlling the operation timing of the scan driving unit 30.

The driving circuit 20 may be disposed in a non-display region NDA provided on one side of the display panel 10. The driving circuit 20 may be formed as an integrated circuit (IC) and mounted on the display panel 10 using a chip on glass (COG) method, a chip on plastic (COP) method, or an ultrasonic bonding method, but the present invention is not limited thereto. For example, the driving circuit 20 may be mounted on a circuit board (not illustrated) other than the display panel 10.

The data driving unit 21 may be mounted on the display panel 10 using a chip on glass (COG) method, a chip on plastic (COP) method, or an ultrasonic bonding method, and the timing control unit 22 may be mounted on a circuit board.

The scan driving unit 30 receives a scan control signal SCS from the timing control unit 22. The scan driving unit 30 generates scan signals according to the scan control signal SCS and supplies them to scan lines S1 to Sn of the display panel 10. The scan driving unit 30 may be formed in a non-display region NDA of the display panel 10 comprising a plurality of transistors. Alternatively, the scan driving unit 30 may be formed as an integrated circuit, in which case it may be mounted on a gate flexible film attached to the other side of the display panel 10.

The power supply circuit 50 may generate voltages necessary for driving the display panel 10 from a main power applied from a system board and supply them to the display panel 10. For example, the power supply circuit 50 may generate a high-potential voltage VDD and a low-potential voltage VSS for driving the light-emitting elements LD of the display panel 10 from the main power supply and supply them to the high-potential voltage line VDDL and the low-potential voltage line VSSL of the display panel 10. In addition, the power supply circuit 50 may generate and supply driving voltages for driving the driving circuit 20 and the scan driving unit 30 from the main power supply.

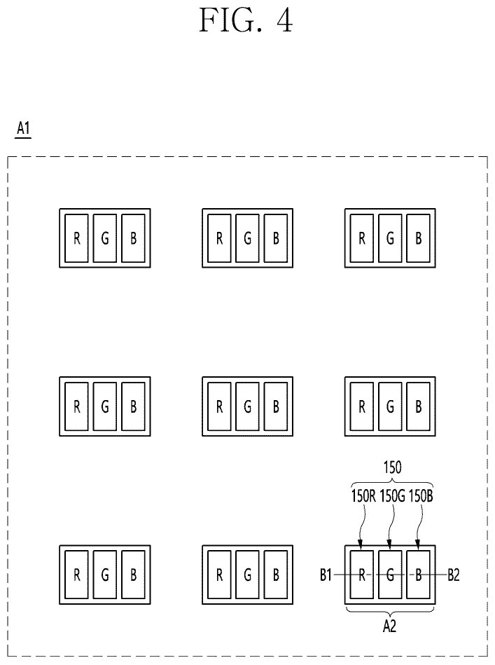

FIG. 4 is an enlarged view of a first panel region in the display device of FIG. 1.

Referring to FIG. 4, the display device 100 of the embodiment may be manufactured by mechanically and electrically connecting a plurality of panel regions such as the first panel region A1 by tiling.

The first panel region A1 may comprise a plurality of semiconductor light-emitting elements 150 disposed for each unit pixel (PX of FIG. 2).

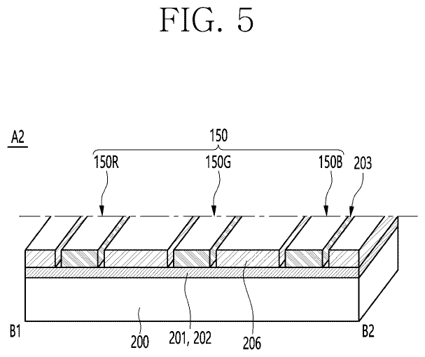

FIG. 5 is an enlarged view of a region A2 of FIG. 4.

Referring to FIG. 5, the display device 100 of the embodiment may comprise a substrate 200, assembly wirings 201 and 202, an insulating layer 206, and a plurality of semiconductor light-emitting elements 150. More components may be included than these.

The assembly wiring may comprise a first assembly wiring 201 and a second assembly wiring 202 that are spaced apart from each other. The first assembly wiring 201 and the second assembly wiring 202 may be provided to generate a dielectrophoretic force (DEP force) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise, but is not limited to, a red semiconductor light-emitting element 150R, a green semiconductor light-emitting element 150G, and a blue semiconductor light-emitting element 150 to form a unit pixel, respectively, and may also comprise a red phosphor and a green phosphor to implement red and green, respectively.

The substrate 200 may be a support member that supports components disposed on the substrate 200, or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), polyethylene terephthalate (PET). In addition, the substrate 200 may be a transparent material, but is not limited thereto. The substrate 200 may function as a support substrate in the display panel, and may also function as an assembly substrate when self-assembling the light-emitting element.

The substrate 200 may be a backplane equipped with circuits, such as transistors ST and DT, capacitors Cst, and signal wiring, in the subpixels PX1, PX2, and PX3 illustrated in FIGS. 2 and 3, but is not limited thereto.

The insulating layer 206 may comprise an organic material having insulation and flexibility, such as polyimide, PAC, PEN, PET, polymer, or an inorganic material such as silicon oxide (SiO2) or silicon nitride series (SiNx), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be an anisotropic conductive film (ACF) or a conductive adhesive layer such as an anisotropic conductive medium, a solution containing conductive particles, etc. The conductive adhesive layer may be a layer that is electrically conductive in a direction vertical to the thickness, but electrically insulating in a direction horizontal to the thickness.

The insulating layer 206 may comprise an assembly hole 203 for inserting the semiconductor light-emitting element 150. Accordingly, during self-assembly, the semiconductor light-emitting element 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element may have different shapes, and may have the assembly holes 203 having shapes corresponding to shapes of the semiconductor light-emitting elements. For example, the assembly holes 203 may comprise a first assembly hole for assembling the red semiconductor light-emitting element 150-1, a second assembly hole for assembling the green semiconductor light-emitting element, and a third assembly hole for assembling the blue semiconductor light-emitting element. For example, the red semiconductor light-emitting element 150-1 may have a circular shape, the green semiconductor light-emitting element may have a first oval shape having a first minor axis and a first major axis, and the blue semiconductor light-emitting element may have a second oval shape having a second minor axis and a second major axis, but is not limited thereto. The second major axis of the oval shape of the blue semiconductor light-emitting element may be larger than the first major axis of the oval shape of the green semiconductor light-emitting element, and the second minor axis of the oval shape of the blue semiconductor light-emitting element may be smaller than the first minor axis of the oval shape of the green semiconductor light-emitting element.

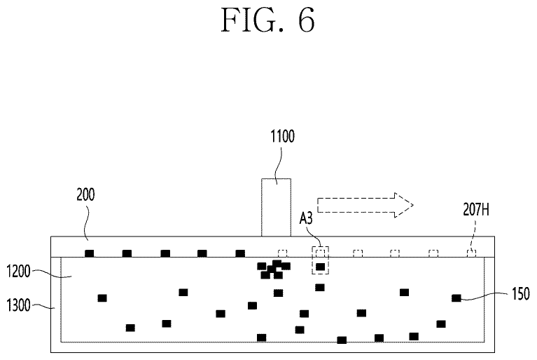

Meanwhile, the method of mounting the semiconductor light-emitting element 150 on the substrate 200 may comprise, for example, a self-assembly method (FIG. 6) and a transfer method.

FIG. 6 is a drawing showing an example in which a light-emitting element according to an embodiment is assembled on a substrate by a self-assembly method.

Based on FIG. 6, an example in which a semiconductor light-emitting element according to an embodiment is assembled on a display panel by a self-assembly method using an electromagnetic field will be described.

The assembly substrate 200 described below may also function as a panel substrate in a display device after assembling the light-emitting element, but the embodiment is not limited thereto.

Referring to FIG. 6, the semiconductor light-emitting element 150 may be put into in a chamber 1300 filled with a fluid 1200, and the semiconductor light-emitting element 150 may be moved to the assembly substrate 200 by a magnetic field generated from the assembly device 1100. At this time, the semiconductor light-emitting element 150 adjacent to the assembly hole 207H of the assembly substrate 200 may be assembled into the assembly hole 207H by the DEP force caused by the electric field of the assembly wirings. The fluid 1200 may be water such as ultrapure water, but is not limited thereto. The chamber may be called a tank, a container, a vessel, etc.

After the semiconductor light-emitting element 150 is put into in the chamber 1300, the assembly substrate 200 may be disposed on the chamber 1300. According to an embodiment, the assembly substrate 200 may be put into the chamber 1300.

The semiconductor light-emitting element 150 may be implemented as a vertical-type semiconductor light-emitting element as illustrated, but is not limited thereto, and a lateral-type light-emitting element may be employed.

Meanwhile, the first assembly wiring 201 and the second assembly wiring 202 form an electric field as an AC voltage is applied, and the semiconductor light-emitting element 150 put into the assembly hole 207H may be fixed by the DEP force caused by the electric field. The gap between the first assembly wiring 201 and the second assembly wiring 202 may be smaller than the width of the semiconductor light-emitting element 150 and the width of the assembly hole 207H, and the assembly position of the semiconductor light-emitting element 150 may be fixed more precisely using the electric field.

An insulating layer 215 is formed on the first assembly wiring 201 and the second assembly wiring 202 to protect the first assembly wiring 201 and the second assembly wiring 202 from the fluid 1200 and prevent leakage of current flowing in the first assembly wiring 201 and the second assembly wiring 202. For example, the insulating layer 215 may be formed as a single layer or multiple layers of an inorganic insulator such as silica or alumina or an organic insulator. The insulating layer 215 may have a minimum thickness to prevent damage to the first assembly wiring 201 and the second assembly wiring 202 during assembly of the semiconductor light-emitting element 150, and may have a maximum thickness to stably assemble the semiconductor light-emitting element 150.

A partition wall 207 may be formed on the upper part of the insulating layer 215. A part of the partition wall 207 may be positioned on the upper part of the first assembly wiring 201 and the second assembly wiring 202, and the remaining regions may be positioned on the upper part of the assembly substrate 200.

Meanwhile, when manufacturing the assembly substrate 200, a part of the partition wall 207 formed on the upper part of the insulating layer 215 may be removed, thereby forming assembly holes 207H in which each of the semiconductor light-emitting elements 150 is coupled and assembled to the assembly substrate 200.

The assembly substrate 200 has assembly holes 207H formed in which the semiconductor light-emitting elements 150 are coupled, and a surface on which the assembly holes 207H are formed may be in contact with the fluid 1200. The assembly holes 207H may guide the exact assembly positions of the semiconductor light-emitting elements 150.

Meanwhile, the assembly holes 207H may have a shape and size corresponding to the shape of the semiconductor light-emitting elements 150 to be assembled at the corresponding positions. Accordingly, it is possible to prevent another semiconductor light-emitting element from being assembled in the assembly hole 207H or a plurality of semiconductor light-emitting elements from being assembled.

Referring again to FIG. 6, after the assembly substrate 200 is disposed in the chamber, the assembly device 1100 applying a magnetic field may move along the assembly substrate 200. The assembly device 1100 may be a permanent magnet or an electromagnet.

The assembly device 1100 may move in contact with the assembly substrate 200 in order to maximize a region affected by the magnetic field within the fluid 1200. Depending on the embodiment, the assembly device 1100 may comprise a plurality of magnetic substances or may comprise a magnetic substance having a size corresponding to that of the assembly substrate 200. In this instance, the movement distance of the assembly device 1100 may be limited within a predetermined range.

The semiconductor light-emitting element 150 in the chamber 1300 may move toward the assembly device 1100 and the assembly substrate 200 by the magnetic field generated by the assembly device 1100.

The semiconductor light-emitting element 150 may be fixed by entering the assembly hole 207H by the DEP force formed by the electric field between the assembly wirings 201 and 202 while moving toward the assembly device 1100.

Specifically, the first and second assembly wirings 201 and 202 form an electric field by the AC power source, and the DEP force may be formed between the assembly wirings 201 and 202 by this electric field. The semiconductor light-emitting element 150 may be fixed to the assembly hole 207H on the assembly substrate 200 by this DEP force.

At this time, a predetermined solder layer (not illustrated) is formed between the semiconductor light-emitting element 150 assembled in the assembly hole 207H of the assembly substrate 200 and the assembly wirings 201 and 202 to improve the binding force of the semiconductor light-emitting element 150.

In addition, a molding layer (not illustrated) may be formed in the assembly hole 207H of the assembly substrate 200 after assembly. The molding layer may be a transparent resin or a resin containing a reflective material or a scattering material.

By the self-assembly method using the electromagnetic field described above, the time required for each semiconductor light-emitting element to be assembled on the substrate may be drastically shortened, so that a large-area, high-pixel display may be implemented more quickly and economically.

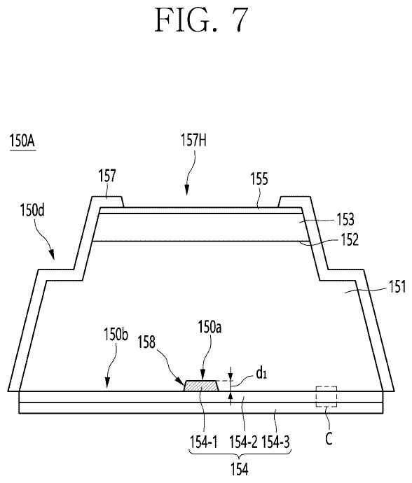

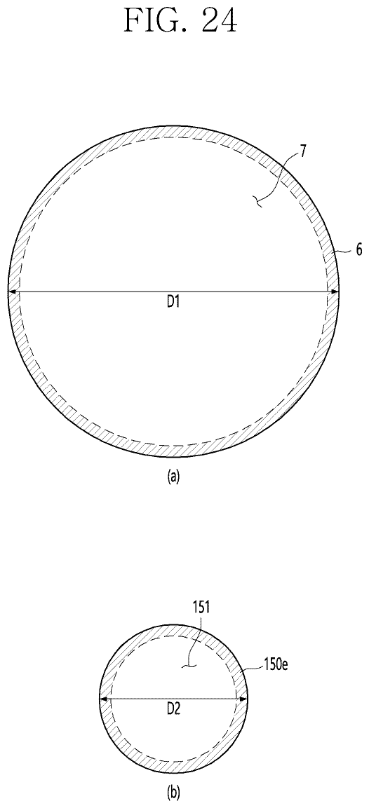

Hereinafter, various embodiments for solving the above-described problem will be described with reference to FIGS. 7 to 32. The omitted descriptions below may be easily understood from the descriptions described above in relation to FIGS. 1 to 6 and the corresponding drawings.

The semiconductor light-emitting element described below may have a size of less than a micrometer. As described above, as the size of the semiconductor light-emitting element decreases, there is a problem that the light luminance decreases. Various embodiments that may improve the light luminance are described below.

In addition, the semiconductor light-emitting element described below may be a vertical-type semiconductor light-emitting element in which current flows vertically.

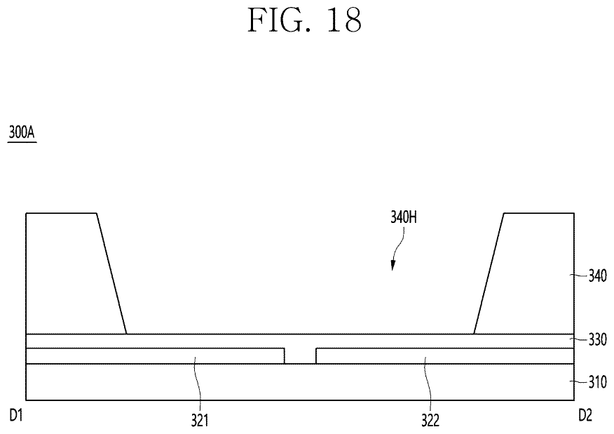

In the description below, when the drawing numeral of the backplane substrate is not given to the corresponding drawing, it may be understood as the backplane substrate 300A illustrated in FIG. 18.

### First Embodiment

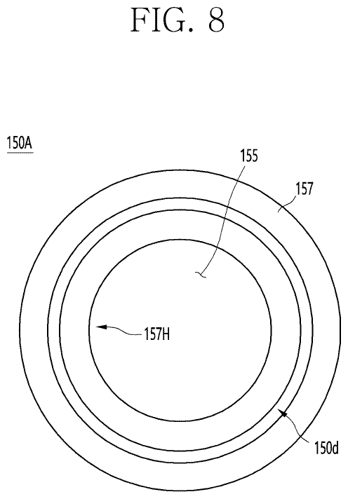

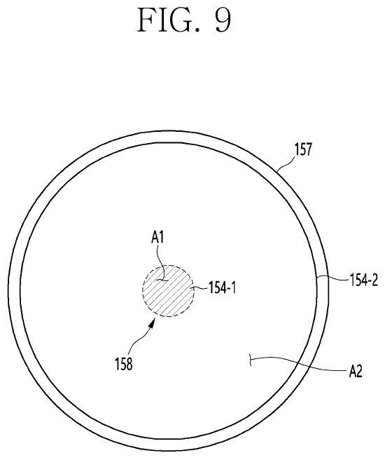

FIG. 7 is a cross-sectional view illustrating a semiconductor light-emitting element according to a first embodiment. FIG. 8 is a plan view illustrating a semiconductor light-emitting element according to the first embodiment. FIG. 9 is a bottom view illustrating a semiconductor light-emitting element according to the first embodiment.

Referring to FIGS. 7 to 9, the semiconductor light-emitting element 150A according to the first embodiment may comprise a light-emitting layer 151 to 153, a passivation layer 157, a first electrode 154, and a second electrode 155.

The light-emitting layer 151 to 153 may emit light of a specific color. The specific color light may be determined by a semiconductor material of the light-emitting layer 151 to 153. The specific color light may be, for example, red light, green light, or blue light. Hereinafter, the light-emitting layer 151 to 153 will be described as emitting red light, but the light-emitting layer 151 to 153 of the embodiment may also emit green light or blue light.

The light-emitting layer 151 to 153 may comprise a plurality of semiconductor layers. For example, the light-emitting layer 151 to 153 may comprise at least one or more first conductivity type semiconductor layer 151, an active layer 152, and at least one or more second conductivity type semiconductor layer 153. The active layer 152 may be disposed on the first conductivity type semiconductor layer 151, and the second conductivity type semiconductor layer 153 may be disposed on the active layer 152. The first conductivity type semiconductor layer 151 may comprise an n-type dopant, and the second conductivity type semiconductor layer 153 may comprise a p-type dopant, but is not limited thereto.

The light-emitting layer 151 to 153 may have a first region 150a and a second region 150b surrounding the first region 150a. A recess 158 having a predetermined depth d1 may be formed under the first region 150a of the light-emitting layer 151 to 153. For example, the recess 158 may be formed on a lower surface of the first conductivity type semiconductor layer 151 corresponding to the first region 150a of the light-emitting layer 151 to 153. The recess 158 may have a bottom surface 158-2 and an inner side. The inner side may have a slope surface 158-1, but may also have a vertical surface. The bottom surface 158-2 may have a straight plane, but is not limited thereto. As will be explained later, the recess 158 may have an ohmic contact layer 154-1 of the first electrode 154 disposed thereon.

The passivation layer 157 may be made of a material having excellent insulating properties, and may protect the light-emitting layer 151 to 153 and prevent leakage current flowing to the lateral part of the light-emitting layer 151 to 153. In addition, the passivation layer 157 may be properly assembled by causing a repulsive force to act on the DEP force during self-assembly, so that the lower side of the semiconductor light-emitting element 150A may face a bottom surface of the assembly hole 340H.

The passivation layer 157 may surround the lateral part of the light-emitting layer 151 to 153. The passivation layer 157 may be disposed in an edge region of the light-emitting layer 151 to 153. The passivation layer 157 may have an opening 157H corresponding to a center region of the light-emitting layer 151 to 153. For example, after the passivation layer 157 is formed on the upper surface of the second electrode 155, the passivation layer 157 corresponding to the central region of the light-emitting layer 151 to 153 may be removed, so that an opening 157H corresponding to the central region of the light-emitting layer 151 to 153 may be formed, and the passivation layer 157 may be formed on the second electrode 155 corresponding to the edge region of the light-emitting layer 151 to 153. Unlike the drawing, the opening 157H may not be formed, and the passivation layer 157 may also be formed on the upper surface of the second electrode 155.

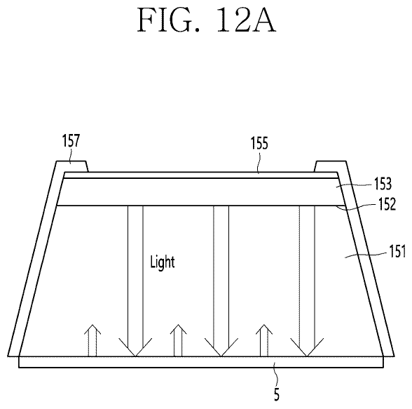

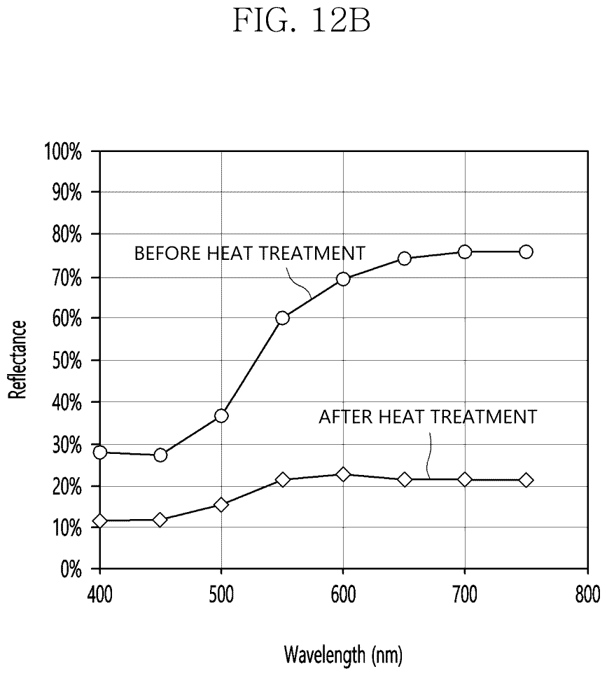

Meanwhile, as described above, according to a non-public internal technology (hereinafter referred to as a comparative example), a method of forming an ohmic contact layer 5 on the entire region of the lower surface of a semiconductor light-emitting element in order to increase light efficiency (or light luminance) has been proposed, as illustrated in FIG. 12A. In order to form the ohmic contact layer 5, a metal film such as AuGe is deposited on the lower surface of the semiconductor light-emitting element and heat treatment is performed, so that the light-emitting layer 151 to 153 have ohmic properties, and then the electrical properties can be improved.

However, as illustrated in FIG. 12B, it may be seen that the light reflectance of the ohmic contact layer 154-1 is significantly different before and after the heat treatment. For example, the light reflectance of the ohmic contact layer 154-1 before the heat treatment is 74% based on the wavelength of 650 nm, whereas the light reflectance is significantly reduced to 22% after the ohmic contact layer 154-1 is heat-treated.

Therefore, a method to improve the light efficiency or luminance by increasing the light reflectance is urgently needed. In the following examples, examples of improving the light efficiency or luminance are described.

Referring again to FIGS. 7 to 9, the first electrode 154 may be disposed under the light-emitting layer 151 to 153.

The first electrode 154 may comprise an ohmic contact layer 154-1, a reflective layer 154-2, and a magnetic layer 154-3. Although not illustrated, the first electrode 154 may comprise more layers than these. The ohmic contact layer 154-1 may comprise Au, AuBe, AuGe, etc. The reflective layer 154-2 may comprise Al, Ag, etc. The magnetic layer 154-3 may comprise Ni, Co, etc. Although not illustrated, the first electrode 154 may also comprise an electrode layer (conductive layer) such as Cu, an anti-oxidation layer such as Mo, an adhesive layer such as Cr, Ti, etc.

According to an embodiment, the structure of the first electrode 154 may be designed to minimize an area of the ohmic contact layer 154-1 and maximize an area of the reflective layer 154-2.

The ohmic contact layer 154-1 may be disposed under the first region 150a of the light-emitting layer 151 to 153. The ohmic contact layer 154-1 may be disposed in a recess 158 formed on the lower side of the first region 150a of the light-emitting layer 151 to 153. The ohmic contact layer 154-1 may be disposed in a recess 158 formed on the lower surface of the first conductivity type semiconductor layer 151 corresponding to the first region 150a of the light-emitting layer 151 to 153. The ohmic contact layer 154-1 may be disposed in a recess 158 formed on a lower surface of the first conductivity type semiconductor layer 151 corresponding to the first region 150a of the light-emitting layer 151 to 153. The ohmic contact layer 154-1 may be in contact with a bottom surface 158-2 of the recess 158. The ohmic contact layer 154-1 may be in contact with an inner side of the recess 158, but is not limited thereto.

The ohmic contact layer 154-1 may be formed to improve ohmic characteristics with respect to the first conductivity type semiconductor layer 151. The ohmic contact layer 154-1 may be made of a metal. For example, the ohmic contact layer 154-1 may comprise Au, AuBe, AuGe, etc.

The lower surface of the ohmic contact layer 154-1 may have a straight plane. The lower surface of the ohmic contact layer 154-1 may be positioned on the same horizontal line as the lower surface of the second region 150b of the light-emitting layer 151 to 153, but is not limited thereto. For example, the thickness of the ohmic contact layer 154-1 may be the same as the depth d1 of the recess 158.

According to an embodiment, the ohmic contact layer 154-1 may be formed only under the first region 150a, which is the central region of the light-emitting layer 151 to 153, so that light efficiency and luminance can be improved by minimizing the probability that light generated in the active layer 152 will be incident and absorbed.

In addition, according to an embodiment, by making the area A1 of the ohmic contact layer 154-1 have a minimum area compared to the area of the lower side of the light-emitting layer 151 to 153, the light efficiency and luminance can be improved by preventing the reduction in light reflectivity due to the ohmic contact layer 154-1. As illustrated in FIG. 9, the area A1 of the ohmic contact layer 154-1 may be 5% to 50% of the area of the lower side of the light-emitting layer 151 to 153.

For example, the ohmic contact layer 154-1 may have a shape corresponding to the shape of the recess 158. As illustrated in FIG. 9, when the recess 158 has a circular shape, the ohmic contact layer 154-1 may each have a circular shape.

The reflective layer 154-2 may be disposed on the lower side of the second region 150b of the light-emitting layer 151 to 153. For example, the reflective layer 154-2 may be in contact with the lower surface of the second region 150b of the light-emitting layer 151 to 153. For example, the reflective layer 154-2 may be in contact with the lower surface of the first conductivity type semiconductor layer 151 corresponding to the second region 150b of the light-emitting layer 151 to 153.

In addition, the reflective layer 154-2 may be disposed under the first region 150a of the light-emitting layer 151 to 153. The reflective layer 154-2 may surround the ohmic contact layer 154-1. The reflective layer 154-2 may be disposed on the lower surface of the ohmic contact layer 154-1. Although not illustrated, a part of the reflective layer 154-2, i.e., the protrusion 154-2a, may be disposed within the recess 158 between the inner side of the recess 158 and the lateral surface of the ohmic contact layer 154-1. In this instance, the protrusion 154-2a may be disposed along the perimeter of the lateral surface of the ohmic contact layer 154-1.

The reflective layer 154-2 may have a function of reflecting light. The reflective layer 154-2 may be made of metal. For example, the reflective layer 154-2 may comprise silver (Ag), aluminum (Al), gold (Au), etc.

According to an embodiment, the reflective layer 154-2 may be formed under the second region 150b, which is an edge region of the light-emitting layer 151 to 153, and may occupy the widest area at the lower side of the light-emitting layer 151 to 153. Accordingly, the light reflectivity can be maximized, and thus the light efficiency and luminance can be improved. As illustrated in FIG. 9, the area A2 of the reflective layer 154-2 may exceed 50% of the area of the lower side of the light-emitting layer 151 to 153. Since the ohmic contact layer 154-1 and the reflective layer 154-2 are disposed in the entire region of the lower side of the light-emitting layer 151 to 153, the arrangement area of the reflective layer 154-2 can be maximized by minimizing the arrangement area of the ohmic contact layer 154-1. For example, in the lower side of the light-emitting layer 151 to 153, 5% of the area A1 may be occupied by the ohmic contact layer 154-1, and the remaining area, that is, 95% of the area A2, may be occupied by the reflective layer 154-2. Accordingly, the probability that the light generated in the active layer 152 may be reflected by the reflective layer 154-2 rather than absorbed by the ohmic contact layer 154-1 can be maximized, so that the light efficiency and luminance can be improved.

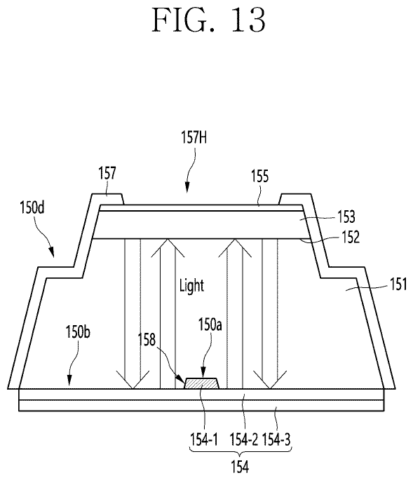

As illustrated in FIG. 13, the reflective layer 154-2 may be disposed in the edge region of the light-emitting layer 151 to 153, i.e., under the second region 150b, and the area A2 of the reflective layer 154-2 exceeds 50% of the area of the lower side of the light-emitting layer 151 to 153, so that most of the light that has traveled downward from the active layer 152 may be reflected upward, thereby improving the light reflectivity.

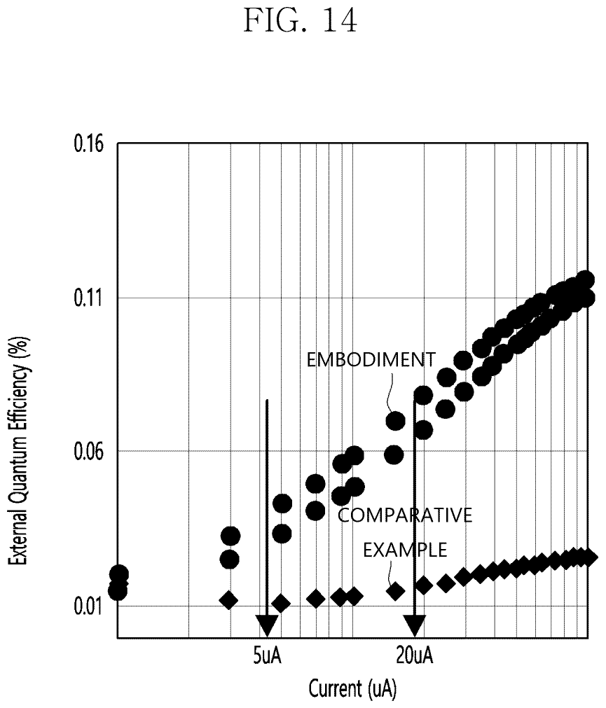

As shown in FIG. 14, the comparative example is a case where the reflective layer 154-2 is not provided, and the embodiment is a case where the arrangement area of the ohmic contact layer 154-1 may be minimized and the arrangement area of the reflective layer 154-2 may be maximized.

It may be seen that the external quantum efficiency may be much higher in the embodiment than in the comparative example. The external quantum efficiency is expressed as the ratio of the number of light particles available to the number of injected charge particles, and may be the product of the internal quantum efficiency and the light extraction efficiency. In particular, it may be seen that the difference in the external quantum efficiency between the comparative example and the embodiment becomes larger as the driving current increases. For example, the inventors confirmed that the external quantum efficiency in the embodiment is 4.7 times greater than that in the comparative example at 20 μA.

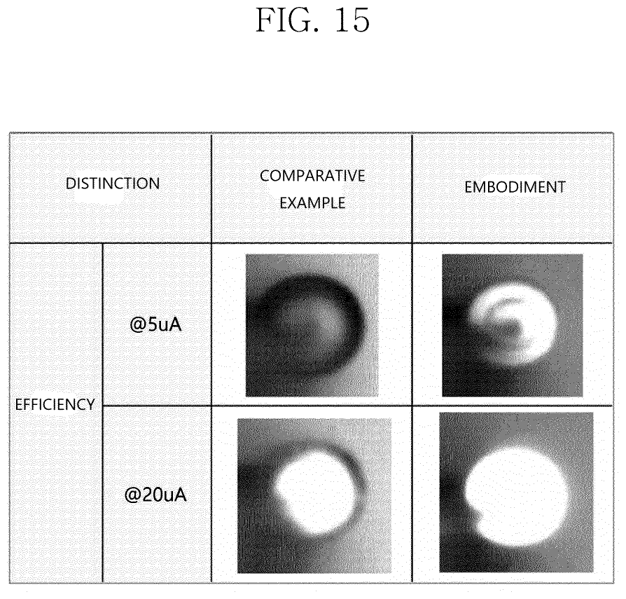

As illustrated in FIG. 15, the comparative example is a case where the reflection layer 154-2 is not provided, and the embodiment is a case where the arrangement area of the ohmic contact layer 154-1 may be minimized and the arrangement area of the reflection layer 154-2 may be maximized.

It may be seen that the light efficiency is significantly higher in the embodiment than in the comparative example at 5 μA and 20 μA, respectively. For example, the applicant confirmed that the light efficiency in the comparative example was 1.2 cd/A at 5 μA, while the light efficiency in the embodiment was 5.3 cd/A, which is approximately a 4.4 times increase.

As described above, the reflective layer 154-2 may be made of metal. However, the reflective layer 154-2 may be made by utilizing a multi-refractive index difference.

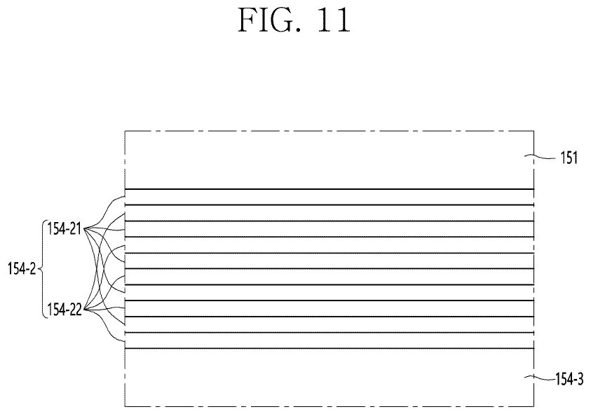

As illustrated in FIG. 11, the reflective layer 154-2 may comprise a plurality of first refractive index layers 154-21 and a plurality of second refractive index layers 154-22. For example, the first refractive index layer 154-21 and the second refractive index layer 154-22 may be alternately laminated. For example, the first refractive index layer 154-21 may be a layer having a low refractive index, and the second refractive index layer 154-22 may be a layer having a high refractive index, but they may be opposite to each other. For example, the first refractive index layer 154-21 may be made of SiO₂ having a refractive index of 1.457 at 632.8 nm, and the second refractive index layer 154-22 may be made of TiO₂ having a refractive index of 2.493 at 632.8 nm.

Referring again to FIGS. 7 to 9, the magnetic layer 154-3 may be a member that is magnetized by magnetization during self-assembly, and the magnetization force may be defined as the degree of magnetization. For example, the greater the magnetization force of the magnetic layer 154-3, the faster the response speed of the semiconductor light-emitting element 150A to the magnet during self-assembly.

The magnetic layer 154-3 may be disposed on the lower side of the light-emitting layer 151 to 153. The magnetic layer 154-3 may be disposed on the lower side of the first region 150a of the light-emitting layer 151 to 153. The magnetic layer 154-3 may be disposed under the reflective layer 154-2 corresponding to the first region 150a of the light-emitting layer 151 to 153. The magnetic layer 154-3 may be disposed on the lower side of the second region 150b of the light-emitting layer 151 to 153. The magnetic layer 154-3 may be disposed under the reflective layer 154-2 corresponding to the second region 150b of the light-emitting layer 151 to 153.

The magnetic layer 154-3 may be in contact with the lower surface of the reflective layer 154-2, but is not limited thereto. The magnetic layer 154-3 may have the same size as the reflective layer 154-2, but is not limited thereto. The magnetic layer 154-3 may have a shape corresponding to the shape of the reflective layer 154-2. For example, when the reflective layer 154-2 has a circular shape, the magnetic layer 154-3 may also have a circular shape.

According to an embodiment, the magnetic layer 154-3 may be disposed in the entire region of the lower side of the light-emitting layer 151 to 153, so that the arrangement area can be maximized, thereby increasing the response speed of the semiconductor light-emitting element 150A to the magnet during self-assembly, and thus improving the assembly rate.

Meanwhile, the second electrode 155 may be disposed on the light-emitting layer 151 to 153. The second electrode 155 may be disposed on the first region 150a of the light-emitting layer 151 to 153. The second electrode 155 may be disposed on the second region 150b of the light-emitting layer 151 to 153. The second electrode 155 may be in contact with the upper surface of the second conductivity type semiconductor layer 153 of the light-emitting layer 151 to 153, but is not limited thereto. Although not illustrated, the size of the second electrode 155 may be smaller than the size of the light-emitting layer 151 to 153. The second electrode 155 is a transparent conductive layer and may comprise ITO, IZO, etc.

Meanwhile, the unexplained numeral 150d may be a multi-stage structure 150d, and when self-assembled, the semiconductor light-emitting element 150A may move to a correct position without greatly shaking up and down or turning over, thereby preventing assembly defects.

Hereinafter, a display device according to the first embodiment will be described.

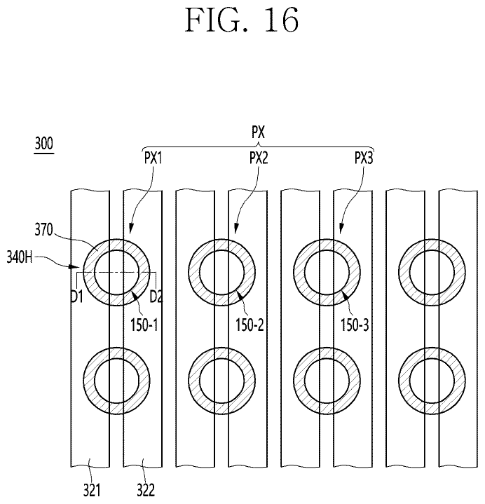

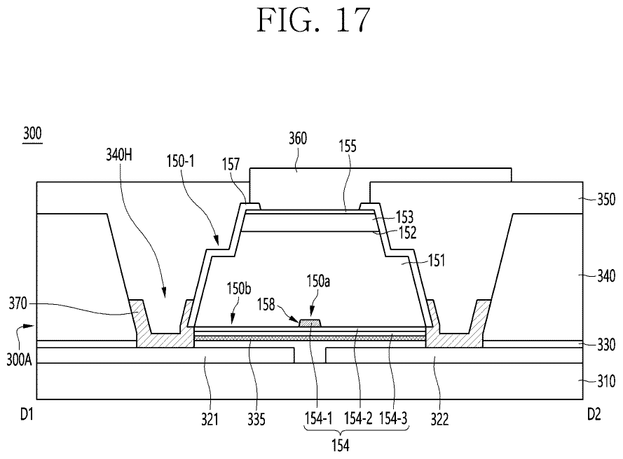

FIG. 16 is a plan view illustrating a display device according to a first embodiment. FIG. 17 is a cross-sectional view taken along line D1-D2 in the display device according to the first embodiment of FIG. 16. FIG. 18 is a cross-sectional view illustrating a backplane substrate of an embodiment.

Referring to FIG. 16, the display device 300 according to the first embodiment comprises a plurality of pixels PX, and each of the plurality of pixels PX may comprise a plurality of subpixels PX1, PX2, and PX3.

For example, semiconductor light-emitting elements 150-1 to 150-3 may be disposed in the plurality of subpixels PX1, PX2, and PX3. For example, at least one or more red semiconductor light-emitting element 150-1 may be disposed on the first subpixel PX1, at least one or more green semiconductor light-emitting element 150-2 may be disposed on the second subpixel PX2, and at least one or more blue semiconductor light-emitting element 150-3 may be disposed on the third subpixel PX3.

The red semiconductor light-emitting element 150-1 may be the semiconductor light-emitting element 150A according to the first embodiment illustrated in FIGS. 7 to 15, but the green semiconductor light-emitting element 150-2 and/or the blue semiconductor light-emitting element 150-3 may also have the same shape, structure, and/or function as the semiconductor light-emitting element 150A according to the first embodiment, except for the semiconductor material of the light-emitting layer 151 to 153.

Meanwhile, the plurality of subpixels PX1 to PX3 may each comprise a first assembly wiring 321 and a second assembly wiring 322. When self-assembly is performed, a DEP force may be formed by an AC voltage applied to the first assembly wiring 321 and the second assembly wiring 322, and the semiconductor light-emitting elements 150-1 to 150-3 in the fluid may be assembled on the corresponding subpixels PX1 to PX3 by this DEP force.

In order to assist in the assembly of the semiconductor light-emitting elements 151-0 to 150-3, the plurality of subpixels PX1 to PX3 may comprise the assembly holes 340H. Since a large DEP force is formed in each the assembly holes 340H, the semiconductor light-emitting elements 150-1 to 150-3 moving in the fluid may be assembled in the corresponding assembly holes 340H by being pulled by the large DEP forces as they pass through the assembly holes 340H.

Referring to FIG. 17 and FIG. 18, the display device 300 according to the first embodiment may comprise a backplane substrate 300A, a second insulating layer 335, a semiconductor light-emitting element 150-1, a connecting electrode 370, a third insulating layer 350, and electrode wiring 360.

The backplane substrate 300A may be prepared in advance. Then, the semiconductor light-emitting element 150-1 may be assembled into the assembly hole 340H of the backplane substrate 300A using a self-assembly process. Then, the connecting electrode 370, the third insulating layer 350, and the electrode wiring 360 may be formed through a post-process, thereby manufacturing the display device 300 according to the first embodiment.

The backplane substrate 300A may comprise a substrate 310, a first assembly wiring 321, a second assembly wiring 322, a first insulating layer 330, and a partition wall 340.

The substrate 310 may be a supporting substrate for supporting components, such as the semiconductor light-emitting element 150-1, the connecting electrode 370, the third insulating layer 350, the electrode wiring 360, etc., of the display device 300 according to the first embodiment, and may be called a lower substrate or a display substrate. Although not illustrated, an upper substrate may be disposed on the electrode wiring 360, but is not limited thereto.

The first assembly wiring 321 may be disposed on the substrate 310. The second assembly wiring 322 may be disposed on the substrate 310.

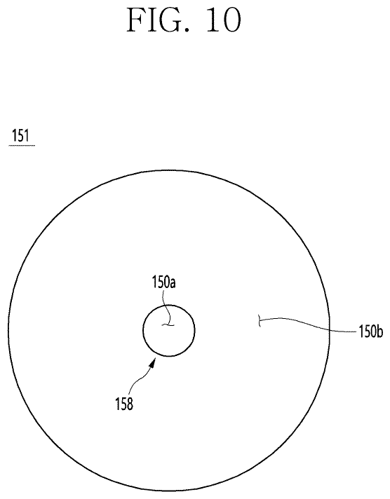

For example, the first assembly wiring 321 and the second assembly wiring 322 may be disposed on the same layer, respectively. For example, the first and second assembly wirings 321 and 322 may be in contact with the upper surface of the substrate 310, but are not limited thereto. For example, the first assembly wiring 321 and the second assembly wiring 322 may be eachdisposed on the same layer. For example, the first assembly wiring 321 and the second assembly wiring 322 may be each disposed parallel to each other. The first assembly wiring 321 and the second assembly wiring 322 may each play a role in assembling the semiconductor light-emitting element 150-1 into the assembly hole 340H using a self-assembly method. That is, when self-assembling, an electric field is generated between the first assembly wiring 321 and the second assembly wiring 322 by the voltage supplied to the first assembly wiring 321 and the second assembly wiring 322, and the semiconductor light-emitting element 150-1 moving by the assembly device (1100 of FIG. 10) may be assembled into the assembly hole 340H by the DEP force formed by the electric field. The assembly hole 340H may have a diameter greater than a diameter of the semiconductor light-emitting element 150-1.

The first assembly wiring 321 and the second assembly wiring 322 may each comprise a plurality of metal layers. Although not illustrated, the first assembly wiring 321 and the second assembly wiring 322 may each comprise a main wiring and an auxiliary electrode. The main wiring of each of the first assembly wiring 321 and the second assembly wiring 322 may be disposed long along one direction of the substrate 310. The auxiliary electrodes of the first assembly wiring 321 and the second assembly wiring 322 may extend from the main wiring toward the assembly hole 340H. The auxiliary electrodes may be electrically connected to the main wiring. The main wiring may be disposed on the auxiliary wiring so that the lower surface of the main wiring may be in contact with the upper surface of the auxiliary wiring, but is not limited thereto.

Meanwhile, although not illustrated, the first assembly wiring 321 and the second assembly wiring 322 may be disposed on different layers.

The first insulating layer 330 may be disposed on the first assembly wiring 321 and the second assembly wiring 322. For example, the first insulating layer 330 may be formed of an inorganic material or an organic material. For example, the first insulating layer 330 may be formed of a material having a permittivity related to the DEP force. For example, the higher the permittivity of the first insulating layer 330, the greater the DEP force may be, but is not limited thereto. The first insulating layer 330 may prevent the fluid from directly being in contact with the first assembly wiring 321 or the second assembly wiring 322 and causing corrosion during self-assembly by the assembly hole 340H of the partition wall 340 formed thereafter.

Although the drawing illustrates that the first insulating layer 330 is removed within the assembly hole 340H, the first insulating layer 330 may remain unremoved within the assembly hole 340H in the backplane substrate 300A. The process of removing the first insulating layer 330 within the assembly hole 340H may be performed after the semiconductor light-emitting element 150-1 is assembled into the assembly hole 340H. The removal of the first insulating layer 330 within the assembly hole 340H may be for the purpose of electrically connecting the connecting electrode 370 with the first assembly wiring 321 and/or the second assembly wiring 322.

The partition wall 340 may be disposed on the first insulating layer 330. The first insulating layer 330 may have an assembly hole 340H. The assembly hole 340H may be formed in each of the plurality of subpixels PX1, PX2, and PX3 of the plurality of pixels PX. That is, one assembly hole 340H may be formed per each of the subpixels PX1, PX2, and PX3, but is not limited thereto. For example, the first insulating layer 330 may be exposed within the assembly hole 340H. For example, the bottom surface 158-2 of the assembly hole 340H may be the upper surface of the first insulating layer 330.

A height (or thickness) of the partition wall 340 may be determined in consideration of a thickness of the semiconductor light-emitting element 150-1.

A self-assembly process may be performed on a backplane substrate 300A configured as described above, so that a plurality of semiconductor light-emitting elements 150-1 to 150-3 may be assembled into a plurality of subpixels PX1, PX2, and PX3 of each of a plurality of pixels PX on the substrate 310.

As an example, a plurality of red semiconductor light-emitting elements 150-1, a plurality of green semiconductor light-emitting elements 150-2, and a plurality of blue semiconductor light-emitting elements 150-3 may be sequentially assembled into a plurality of subpixels PX1, PX2, and PX3 of each of a plurality of pixels PX on the substrate 310.

As another example, a plurality of red semiconductor light-emitting elements 150-1, a plurality of green semiconductor light-emitting elements 150-2, and a plurality of blue semiconductor light-emitting elements 150-3 may be simultaneously assembled into a plurality of subpixels PX1, PX2, and PX3 of each of a plurality of pixels PX on the substrate 310. To this end, a plurality of red semiconductor light-emitting elements 150-1, a plurality of green semiconductor light-emitting elements 150-2, and a plurality of blue semiconductor light-emitting elements 150-3 may be dropped into a fluid in the chamber and mixed. Subsequently, the same self-assembly process may be performed, so that a plurality of red semiconductor light-emitting elements 150-1, a plurality of green semiconductor light-emitting elements 150-2, and a plurality of blue semiconductor light-emitting elements 150-3 may be simultaneously assembled into a plurality of subpixels PX1, PX2, and PX3 of each of a plurality of pixels PX on the substrate 310.

For simultaneous self-assembly, the red semiconductor light-emitting element 150-1, the green semiconductor light-emitting element 150-2, and the blue semiconductor light-emitting element 150-3 may each have exclusivity with respect to each other. That is, the shapes or sizes of the red semiconductor light-emitting element 150-1, the green semiconductor light-emitting element 150-2, and the blue semiconductor light-emitting element 150-3 may each be different. For example, the red semiconductor light-emitting element 150-1 may have a circular shape, the green semiconductor light-emitting element 150-2 may have a first oval shape having a first minor axis and a first major axis, and the blue semiconductor light-emitting element 150-3 may have a second oval shape. At this time, the second oval shape may have a second minor axis smaller than the first minor axis and a second major axis larger than the first major axis.

As described above, a part of the first electrode 154, that is, the ohmic contact layer 154-1, may be disposed under the first region 150a of the light-emitting layer 151 to 153, the reflective layer 154-2 may be disposed under the ohmic contact layer 154-1 as well as under the second region 150b of the light-emitting layer 151 to 153, and the magnetic layer 154-3 may be disposed under the reflective layer 154-2. At this time, since the ohmic contact layer 154-1 is disposed within the recess 158 formed on the lower side of the first region 150a of the light-emitting layer 151 to 153, the lower surface of the reflective layer 154-2 and/or the lower surface of the magnetic layer 154-3 disposed under the ohmic contact layer 154-1 may have a straight plane. In this way, since the lower side of the semiconductor light-emitting element 150-1 has a straight plane, the semiconductor light-emitting element 150-1 may be properly assembled in the assembly hole 340H without being shaken left and right or flipped over in the fluid during self-assembly.

Meanwhile, after the semiconductor light-emitting element 150-1 is assembled, an electrical connection may be formed using a post-process. That is, the connecting electrode 370, the third insulating layer 350, and the electrode wiring 360 may be formed using a post-process.

The connecting electrode 370 may be disposed in the assembly hole 340H. The connecting electrode 370 may electrically connect the semiconductor light-emitting element 150-1 and the first assembly wiring 321 and/or the second assembly wiring 322. For example, the connecting electrode 370 may electrically connect the first electrode 154 of the semiconductor light-emitting element 150-1 to the first assembly wiring 321 and/or the second assembly wiring 322. For example, the connecting electrode 370 may be electrically connected to the lateral surface of the reflective layer 154-2 and/or the lateral surface of the magnetic layer 154-3 of the first electrode 154.

The connecting electrode 370 may be formed using an electroplating or sputtering method.

As an example, the connecting electrode 370 may be formed using an electroplating process. That is, after the plating target, for example, the substrate 310, is immersed in an electrolyte, the first assembly wiring 321 and/or the second assembly wiring 322 may be connected to the cathode electrode and voltage may be applied, so that a metal film may be coated on the first assembly wiring 321 and/or the second assembly wiring 322, thereby forming a connecting electrode 370.

As the metal film is coated on the first assembly wiring 321 and/or the second assembly wiring 322 and gradually becomes thicker, the connecting electrode 370 may be formed along the perimeter of the semiconductor light-emitting element 150-1 in the assembly hole 340H as well as on the lower side of the semiconductor light-emitting element 150-1.

As another example, a metal film may be formed on the substrate 310 using a sputtering process and then patterned, so that the connecting electrode 370 may be formed along the perimeter of the semiconductor light-emitting element 150-1 in the assembly hole 340H. In addition, a wide separation space corresponding to the sum of the thickness t4 of the first insulating layer 330 and the step d1 may be formed, so that the metal film may also be formed in the separation space. Accordingly, the formation of the connecting electrode 370 may be facilitated, and the contact area between the connecting electrode 370 and the first electrode 154 can be maximized, so that the luminous efficiency and the light luminance can be significantly improved.

Although not illustrated, instead of the connecting electrode 370, another electrode wiring 360 may be connected to the lateral part of the semiconductor light-emitting element 150-1 through the third insulating layer 350, and may be spaced apart from the electrode wiring 360.

The second insulating layer 335 may be disposed between the semiconductor light-emitting element 150-1 and the first insulating layer 330 to fix the semiconductor light-emitting element 150-1 to the first insulating layer 330.

The second insulating layer 335 may have a shape corresponding to the shape of the semiconductor light-emitting element 150-1. For example, the diameter (or width) of the second insulating layer 335 may be the same as the diameter (or width) of the semiconductor light-emitting element 150-1, but is not limited thereto. For example, the second insulating layer 335 may have a shape corresponding to the shape of the first conductivity type semiconductor layer 151 of the semiconductor light-emitting element 150-1 and/or the shape of the first electrode 154. For example, the thickness of the second insulating layer 335 may be smaller than the thickness of the first insulating layer 330. For example, the thickness of the second insulating layer 335 may be smaller than the thickness of the first electrode 154 of the semiconductor light-emitting element 150-1.

The third insulating layer 350 may be disposed on the partition wall 340. The third insulating layer 350 may be disposed on the semiconductor light-emitting element 150-1. The third insulating layer 350 may be disposed on the connecting electrode 370 disposed in the assembly hole 340H. The third insulating layer 350 may be a planarization layer for easily forming the electrode wiring 360 or other layers. Accordingly, the upper surface of the third insulating layer 350 may have a straight plane. The first insulating layer 330 and the third insulating layer 350 may be made of an organic material or an inorganic material. For example, at least one or more insulating layer among the first insulating layer 330 and the third insulating layer 350 may be made of an organic material.

The electrode wiring 360 may be disposed on the third insulating layer 350 and may be electrically connected to the semiconductor light-emitting element 150-1 through the third insulating layer 350. For example, the electrode wiring 360 may be electrically connected to the upper side of the light-emitting layer 151 to 153 through the third insulating layer 350 and the passivation layer 157 of the semiconductor light-emitting element 150-1.

Therefore, the semiconductor light-emitting element 150-1 may emit light by the voltage supplied to the first assembly wiring 321 and/or the second assembly wiring 322 and the electrode wiring 360.

### Second Embodiment

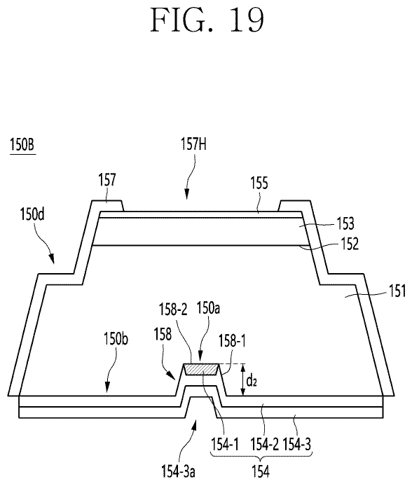

FIG. 19 is a cross-sectional view illustrating a semiconductor light-emitting element according to a second embodiment.

The second embodiment is the same as the first embodiment except for the depth d2 of the recess 158. In the second embodiment, components having the same shape, structure, and/or function as those in the first embodiment are given the same drawing reference numerals, and detailed descriptions thereof are omitted.

Referring to FIG. 19, the semiconductor light-emitting element 150B according to the second embodiment may comprise a light-emitting layer 151 to 153, a passivation layer 157, a first electrode 154, and a second electrode 155. The semiconductor light-emitting element 150B according to the second embodiment may be a red semiconductor light-emitting element (150-1 of FIG. 16). The green semiconductor light-emitting element 150-2 or the blue semiconductor light-emitting element 150-3 may also have the same structure as the semiconductor light-emitting element 150B according to the second embodiment, except that only the materials of the light-emitting layer 151 to 153 are different.

A recess 158 may be formed in the lower side of the first region 150a of the light-emitting layer 151 to 153. The depth d2 of the recess 158 of the second embodiment may be greater than the depth d1 of the recess 158 of the first embodiment (FIG. 7).

The first electrode 154 may be disposed on the lower side of the light-emitting layer 151 to 153, and the second electrode 155 may be disposed on the upper side of the light-emitting layer 151 to 153. The first electrode 154 may comprise an ohmic contact layer 154-1, a reflective layer 154-2, and a magnetic layer 154-3. Although not illustrated, the first electrode 154 may comprise more layers than these.

The recess 158 may have a bottom surface 158-2 and a slope surface 158-1. As the depth d2 of the recess 158 increases, the length or area of the slope surface 158-1 may increase.

An ohmic contact layer 154-1 may be disposed in the recess 158. At this time, the thickness of the ohmic contact layer 154-1 may be the same as the thickness of the ohmic contact layer 154-1 of the first embodiment (FIG. 7), but is not limited thereto.

In the second embodiment, the thickness of the ohmic contact layer 154-1 may be smaller than the depth d2 of the recess 158. Accordingly, the lower surface of the ohmic contact layer 154-1 may be positioned higher than the lower surface of the second region 150b of the light-emitting layer 151 to 153. The ohmic contact layer 154-1 may be disposed on the bottom surface 158-2 of the recess 158.

Meanwhile, the reflective layer 154-2 may be disposed on the lower side of the light-emitting layer 151 to 153, and the magnetic layer 154-3 may be disposed under the reflective layer 154-2. The reflective layer 154-2 may be disposed under the second region 150b of the light-emitting layer 151 to 153. The reflective layer 154-2 may be disposed under the ohmic contact layer 154-1. The reflective layer 154-2 may surround the ohmic contact layer 154-1.

The reflective layer 154-2 and the magnetic layer 154-3 may be disposed within the recess 158. The reflective layer 154-2 and the magnetic layer 154-3 may be disposed under the ohmic contact layer 154-1 within the recess 158. The reflective layer 154-2 may be disposed on the slope surface 158-1 of the recess 158. A part of the reflective layer 154-2, i.e., the protrusion 154-2a, may surround the ohmic contact layer 154-1 within the recess 158. The depth d2 of the recess 158 may be greater than the sum of the thickness of the ohmic contact layer 154-1, the thickness of the reflective layer 154-2, and the thickness of the magnetic layer 154-3. Accordingly, the magnetic layer 154-3 may be formed in a recess 154-3a corresponding to the recess 158 formed in the lower side of the light-emitting layer 151 to 153.

According to the second embodiment, since the depth d2 of the recess 158 is large, the ohmic contact layer 154-1 may be disposed on the bottom surface 158-2 of the recess 158, and the reflective layer 154-2 may be disposed on the inner side of the recess 158. Accordingly, compared to the first embodiment (FIG. 7), the area A2 of the reflective layer 154-2 of the second embodiment can be further increased, so that the light efficiency and luminance can be improved due to the increase in the light reflectivity.

According to the second embodiment, the magnetic layer 154-3 may be also disposed on the reflective layer 154-2 disposed on the inner side of the recess 158, so that the area of the magnetic layer 154-3 may be also further increased compared to the first embodiment (FIG. 7), so that the response speed to the magnet during self-assembly can increase, thereby improving the assembly rate.

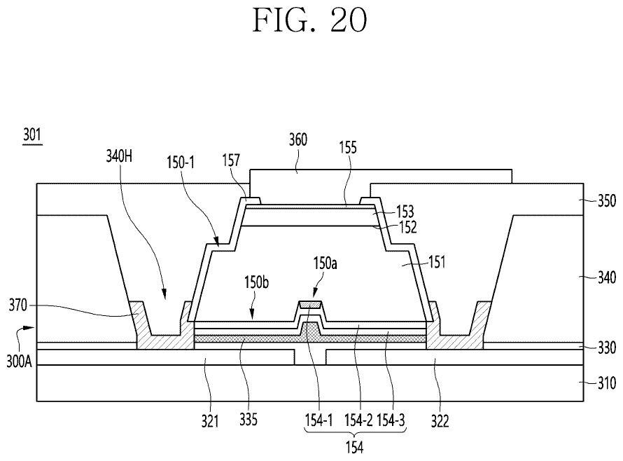

FIG. 20 is a cross-sectional view illustrating a display device according to the second embodiment.

Referring to FIG. 20, the display device 301 according to the second embodiment may comprise a backplane substrate 300A, a second insulating layer 335, a semiconductor light-emitting element 150-1, a connecting electrode 370, a third insulating layer 350, and an electrode wiring 360.

The backplane substrate 300A may comprise a substrate 310, a first assembly wiring 321, a second assembly wiring 322, a first insulating layer 330, and a partition wall 340.

The self-assembly may be performed on the backplane substrate 300A, and the semiconductor light-emitting element 150-1 may be assembled into the assembly hole 340H, and then a post-process may be performed to sequentially form the second insulating layer 335, the semiconductor light-emitting element 150-1, the connecting electrode 370, the third insulating layer 350, and the electrode wiring 360.

The semiconductor light-emitting element 150-1 may be a red semiconductor light-emitting element, and may be a semiconductor light-emitting element (150B of FIG. 19) according to the second embodiment.

Since the depth d2 of the semiconductor light-emitting element 150-1 is greater than the sum of the thickness of the ohmic contact layer 154-1, the thickness of the reflective layer 154-2, and the thickness of the magnetic layer 154-3, a recess 154-3a of the magnetic layer 154-3 may be formed within the recess 158.

As illustrated in FIG. 20, the second insulating layer 335 may be disposed not only between the lower side of the semiconductor light-emitting element 150-1 and the first insulating layer 330, but also in the recess 154-3a of the magnetic layer 154-3, so that the contact area between the magnetic layer 154-3 and the second insulating layer 335, that is, the contact area between the semiconductor light-emitting element 150-1 and the second insulating layer 335, can be expanded. Thus, the semiconductor light-emitting element 150-1 can be more firmly fixed to the first insulating layer 330, and peeling of the semiconductor light-emitting element 150-1 can be prevented.

### Third Embodiment

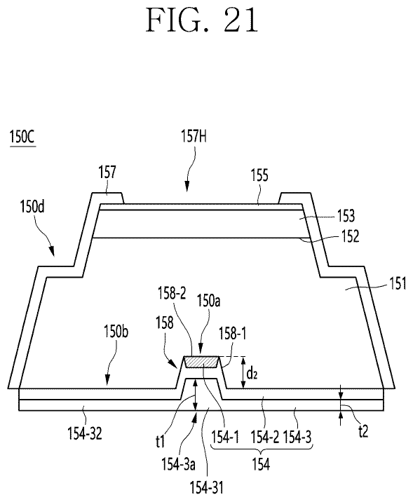

FIG. 21 is a cross-sectional view illustrating a semiconductor light-emitting element according to a third embodiment.

The third embodiment is the same as the second embodiment except that the entire region of the lower surface of the magnetic layer 154-3 has a straight plane.

Referring to FIG. 21, the semiconductor light-emitting element 150C according to the third embodiment may comprise a light-emitting layer 151 to 153, a passivation layer 157, a first electrode 154, and a second electrode 155. The semiconductor light-emitting element 150C according to the third embodiment may be a red semiconductor light-emitting element (150-1 of FIG. 16). The green semiconductor light-emitting element 150-2 or the blue semiconductor light-emitting element 150-3 may also have the same structure as the semiconductor light-emitting element 150C according to the third embodiment, except that the materials of the light-emitting layer 151 to 153 are different.

A recess 158 may be formed in the lower side of the first region 150a of the light-emitting layer 151 to 153. The depth d2 of the recess 158 of the third embodiment may be greater than the depth d1 of the recess 158 of the first embodiment (FIG. 7).

The first electrode 154 may be disposed on the lower side of the light-emitting layer 151 to 153, and the second electrode 155 may be disposed on the upper side of the light-emitting layer 151 to 153. The first electrode 154 may comprise an ohmic contact layer 154-1, a reflective layer 154-2, and a magnetic layer 154-3. Although not illustrated, the first electrode 154 may comprise more layers than these.

The ohmic contact layer 154-1, the reflective layer 154-2, and the magnetic layer 154-3 may be disposed in the recess 158. The depth d2 of the recess 158 may be equal to the sum of the thickness of the ohmic contact layer 154-1, the thickness of the reflective layer 154-2, and the thickness of the magnetic layer 154-3. Specifically, a lower surface of the ohmic contact layer 154-1 within the recess 158 may be positioned higher than a lower surface of the second region 150b of the light-emitting layer 151 to 153. A lower surface of the reflective layer 154-2 within the recess 158 may be positioned higher than a lower surface of the second region 150b of the light-emitting layer 151 to 153. A lower surface of the magnetic layer within the recess 158 may be positioned lower than a lower surface of the second region 150b of the light-emitting layer 151 to 153. In other words, the lower surface of the magnetic layer 154-3 may be positioned on the same horizontal line in the first region 150a and the second region 150b of the light-emitting layer 151 to 153. That is, the magnetic layer 154-3 may comprise a first magnetic region 154-31 corresponding to the first region 150a of the light-emitting layer 151 to 153 and a second magnetic region 154-32 corresponding to the second region 150b of the light-emitting layer 151 to 153. In this instance, the thickness t1 of the first magnetic region 154-31 may be greater than the thickness t2 of the second magnetic region 154-32.

According to the third embodiment, even if the depth d2 of the recess 158 is as large as in the second embodiment (FIG. 19), since the lower surface of the light-emitting layer 151 to 153, that is, the lower surface of the magnetic layer 154-3 of the first electrode 154, have a straight plane, the semiconductor light-emitting element 150C may be assembled without being tilted left and right or turned over in the fluid during self-assembly.

### Fourth Embodiment

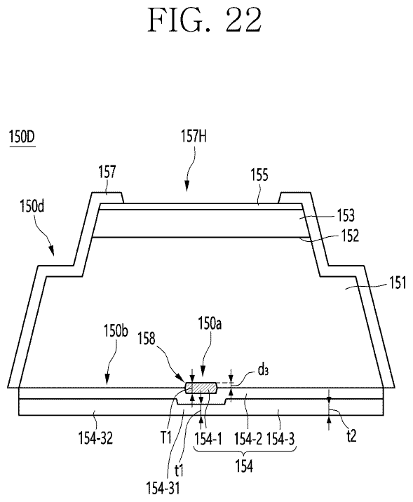

FIG. 22 is a cross-sectional view illustrating a semiconductor light-emitting element according to a fourth embodiment.

The fourth embodiment is the same as the first to third embodiments except that the thickness T1 of the ohmic contact layer 154-1 is greater than the depth d3 of the recess 158. In the fourth embodiment, components having the same shape, structure, and/or function as those of the first to third embodiments are given the same drawing reference numerals, and detailed descriptions thereof are omitted.

Referring to FIG. 22, the semiconductor light-emitting element 150D according to the fourth embodiment may comprise a light-emitting layer 151 to 153, a passivation layer 157, a first electrode 154, and a second electrode 155. The semiconductor light-emitting element 150D according to the fourth embodiment may be a red semiconductor light-emitting element (150-1 of FIG. 16). The green semiconductor light-emitting element 150-2 or the blue semiconductor light-emitting element 150-3 may also have the same structure as the semiconductor light-emitting element 150D according to the fourth embodiment, except that the materials of the light-emitting layer 151 to 153 are different.

A recess 158 may be formed in the lower side of the first region 150a of the light-emitting layer 151 to 153.

The first electrode 154 may be disposed on the lower side of the light-emitting layer 151 to 153, and the second electrode 155 may be disposed on the upper side of the light-emitting layer 151 to 153. The first electrode 154 may comprise an ohmic contact layer 154-1, a reflective layer 154-2, and a magnetic layer 154-3. Although not illustrated, the first electrode 154 may comprise more layers than these.

An ohmic contact layer 154-1, a reflective layer 154-2, and a magnetic layer 154-3 may be disposed in the recess 158. Here, a depth d3 of the recess 158 may be smaller than a thickness T1 of the ohmic contact layer 154-1. When the ohmic contact layer 154-1 is disposed in the recess 158, a lower surface of the ohmic contact layer 154-1 may be positioned lower than a lower surface of the second region 150b of the light-emitting layer 151 to 153. In other words, the ohmic contact layer 154-1 may protrude lower than the second region 150b of the light-emitting layer 151 to 153.

The reflective layer 154-2 may be disposed on the ohmic contact layer 154-1 and the second region 150b of the light-emitting layer 151 to 153. Since the thickness of the reflective layer 154-2 is smaller than that of the ohmic contact layer 154-1, the reflective layer 154-2 disposed under the ohmic contact layer 154-1 may also protrude downwards.

The magnetic layer 154-3 may be disposed under the reflective layer 154-2. At this time, the entire region of the lower surface of the magnetic layer 154-3 may have a straight plane. The magnetic layer 154-3 may comprise a first magnetic region 154-31 corresponding to the first region 150a of the light-emitting layer 151 to 153 and a second magnetic region 154-32 corresponding to the second region 150b of the light-emitting layer 151 to 153. In this instance, the thickness t1 of the first magnetic region 154-31 may be smaller than the thickness t2 of the second magnetic region 154-32.

### Fifth Embodiment

The fifth embodiment is the same as the first to fourth embodiments except that the recess 158 has a very deep cone shape. In the fifth embodiment, components having the same shape, structure, and/or function as those of the first to fourth embodiments are given the same drawing numerals, and detailed descriptions thereof are omitted.

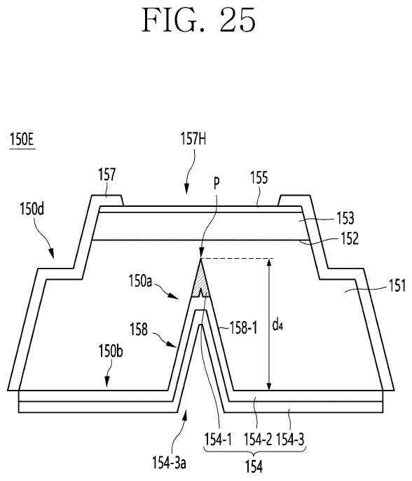

Before describing the semiconductor light-emitting element (150E of FIG. 25) according to the fifth embodiment, the related background technology will be described.

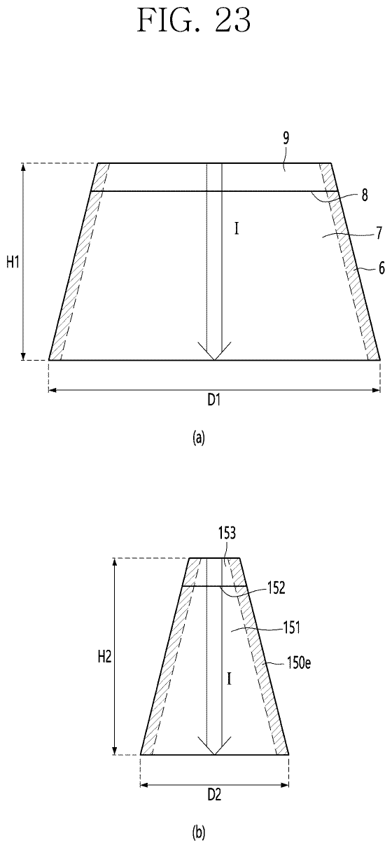

FIG. 23(a) and FIG. 23(b) illustrate the size of a semiconductor light-emitting element for lighting, and FIG. 23(a) and FIG. 23(b) illustrate the size of a semiconductor light-emitting element according to an embodiment.

While the diameter D1 of a semiconductor light-emitting element for lighting is typically several hundred micrometers to several millimeters, the diameter D2 of a semiconductor light-emitting element according to an embodiment used as a subpixel of a high-resolution or ultra-high-resolution display device is 10 micrometers or less, and recently, it may be several nanometers or tens of nanometers.

Meanwhile, in order to emit light as a semiconductor light-emitting element, it must be composed of a large number of semiconductor layers, regardless of whether it is for lighting or display. For convenience, a typical semiconductor light-emitting element for lighting is composed of a first conductivity type semiconductor layer 7, an active layer 8, and a second conductivity type semiconductor layer 9, and a semiconductor light-emitting element according to an embodiment may be composed of a first conductivity type semiconductor layer 151, an active layer 152, and a second conductivity type semiconductor layer 153. Accordingly, the height H1 of the semiconductor light-emitting element for lighting and the height H2 of the semiconductor light-emitting element according to an embodiment may be the same. As a result, the diameter may be significantly reduced rather than the height as the semiconductor light-emitting element for lighting changes from the semiconductor light-emitting element according to the embodiment.

Meanwhile, as is widely known, a mesa etching process may be performed to separate a large number of semiconductor layers into chip units after they are deposited using a deposition process. In this instance, the mesa etching process is a physical etching process using plasma, and during the mesa etching process, the etched surface, that is, the surface of the outer side of each of the plurality of semiconductor layers and a part of its interior may be damaged, resulting in non-luminous regions 6 and 150e where light is not emitted.

In the semiconductor light-emitting element for lighting, since the area occupied by the non-luminous region 6 is small compared to the entire region, a large area of the active layer 152 may be used as the luminous region. Accordingly, in the semiconductor light-emitting element for lighting, light is generated in a wider area of the active layer 152 through a structural change that disperses the current.

In contrast, in the semiconductor light-emitting element according to the embodiment, the area occupied by the non-luminous region 150e is very large compared to the entire region. In other words, most of the area of the active layer 152 is included in the non-luminous region 150e, so that there is not much area in the active layer 152 where light may be generated through a structural change such as current dispersion. Accordingly, in the semiconductor light-emitting element according to the embodiment, a structural change such as current dispersion does not greatly contribute to improving the light efficiency or luminance.

The applicant, referring to this background technology, proposed a method for improving light efficiency and/or luminance through a different structural change (FIG. 25) instead of a structural change such as current distribution in a semiconductor light-emitting element according to an embodiment used for subpixels of a high-resolution or ultra-high-resolution display device.

FIG. 25 is a cross-sectional view illustrating a semiconductor light-emitting element according to a fifth embodiment.

Referring to FIG. 25, a semiconductor light-emitting element 150E according to a fifth embodiment may comprise a light-emitting layer 151 to 153, a passivation layer 157, a first electrode 154, and a second electrode 155. A semiconductor light-emitting element 150E according to a fifth embodiment may be a red semiconductor light-emitting element (150-1 of FIG. 16). The green semiconductor light-emitting element 150-2 or the blue semiconductor light-emitting element 150-3 may also have the same structure as semiconductor light-emitting element 150E according to the fifth embodiment, except that only the materials of the light-emitting layer 151 to 153 are different.

A recess 158 may be formed in the lower side of the first region 150a of the light-emitting layer 151 to 153. The recess 158 may have a cone shape having a very deep depth d4. The depth d4 of the recess 158 may be defined as the distance between the peak P of the recess 158 and the lower surface of the second region 150b of the light-emitting layer 151 to 153. For example, the depth d4 of the recess 158 may be at least 1/2 of the thickness of the first conductivity type semiconductor layer 151 of the light-emitting layer 151 to 153. For example, the peak P of the recess 158 may be positioned higher than a step region in the multi-stage structure 150d. The peak P of the recess 158 may be adjacent to the active layer 152, but may not be in contact with the active layer 152. The recess 158 may have a slope surface 158-1. As the depth d4 increases, the length or area of the slope surface 158-1 may increase.

The first electrode 154 may be disposed on the lower side of the light-emitting layer 151 to 153, and the second electrode 155 may be disposed on the upper side of the light-emitting layer 151 to 153. The first electrode 154 may comprise an ohmic contact layer 154-1, a reflective layer 154-2, and a magnetic layer 154-3. Although not illustrated, the first electrode 154 may comprise more layers than these.

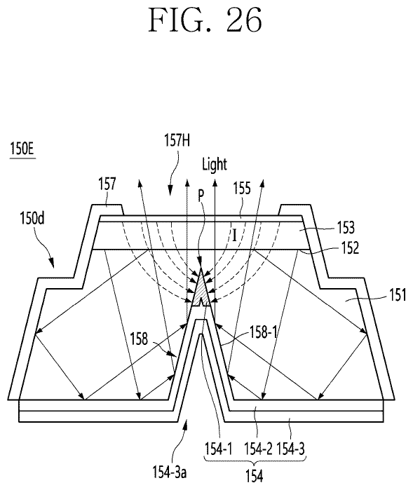

An ohmic contact layer 154-1, a reflective layer 154-2, and a magnetic layer 154-3 may be disposed in the recess 158. The ohmic contact layer 154-1 may be disposed at and around the peak P of the recess 158. Since the ohmic contact layer 154-1 is disposed at and around the peak P of the recess 158, the ohmic contact layer 154-1 may be disposed very adjacent to the active layer 152. That is, as illustrated in FIG. 26, when a driving current I flows through the semiconductor light-emitting element 150E, shortest current paths may be formed between the second electrode 155 and the ohmic contact layer 154-1 with the active layer 152 therebetween. Since a shorter current path results in less current loss, more light may be generated by the driving current flowing through the shortest current paths, thereby improving light efficiency and luminance. In addition, since the driving current starting from the second electrode 155 flows toward the peak P of the recess 158 and the ohmic contact layer 154-1 disposed in the vicinity thereof, the shortest current paths may be formed not only in the center region of the second electrode 155 but also between the edge region and the ohmic contact layer 154-1, so that more light may be generated in each corresponding region of the active layer 152 passing through each of the shortest current paths, Thus, the light efficiency and luminance can be significantly improved.

The reflective layer 154-2 may be disposed under the second region 150b of the light-emitting layer 151 to 153. In addition, the reflective layer 154-2 may be disposed on the slope surface 158-1 of the recess 158. The reflective layer 154-2 may be in contact with the slope surface 158-1 of the recess 158, but is not limited thereto. The magnetic layer 154-3 may be disposed under the reflective layer 154-2.

As illustrated in FIG. 26, since the depth d4 of the recess 158 is very large, the length or area of the slope surface 158-1 of the recess 158 can also be significantly increased. Accordingly, the area of the reflection layer 154-2 disposed on the slope surface 158-1 of the recess 158 can also increase greatly and become inclined, and since the reflection layer 154-2 is also disposed under the second region 150b of the light-emitting layer 151 to 153, light traveling downward from the active layer 152 may be reflected not only by the reflection layer 154-2 disposed under the second region 150b of the light-emitting layer 151 to 153, but also by the reflection layer 154-2 disposed on the slope surface 158-1 of the recess 158, so that the light efficiency and luminance can be further improved.

Meanwhile, the magnetic layer 154-3 may be also disposed on the slope surface 158-1 of the recess 158 having a very deep depth d4 as well as under the second region 150b of the light-emitting layer 151 to 153 or under the ohmic contact layer 154-1, so that the area of the magnetic layer 154-3 can be maximized. Thus, the response speed to the magnet during self-assembly can be significantly increased, and thus the assembly rate can be further improved.

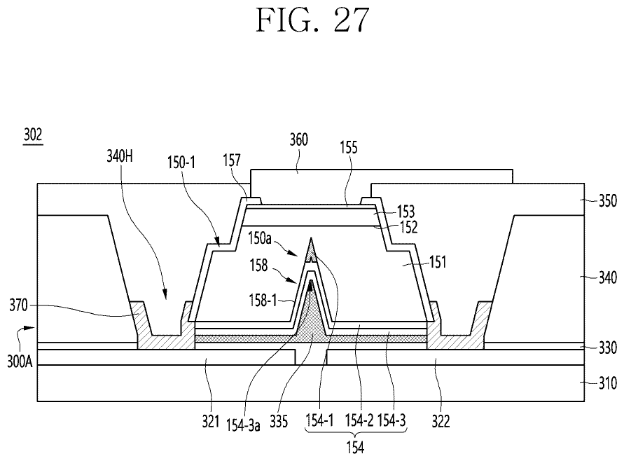

FIG. 27 is a cross-sectional view illustrating a display device according to a third embodiment.

Referring to FIG. 27, the display device 302 according to the third embodiment may comprise a backplane substrate 300A, a second insulating layer 335, a semiconductor light-emitting element 150-1, a connecting electrode 370, a third insulating layer 350, and electrode wiring 360.

The semiconductor light-emitting element 150-1 may be a red semiconductor light-emitting element, which may be a semiconductor light-emitting element (150E of FIG. 25) according to the fifth embodiment. The green semiconductor light-emitting element 150-2 or the blue semiconductor light-emitting element 150-3 provided in the display device 302 according to the third embodiment may have a different semiconductor material, but may have a basic structure identical to or similar to that of the semiconductor light-emitting element (150E of FIG. 25) according to the fifth embodiment.

As described above, the depth d4 of the recess 158 may be made to be at least half the thickness of the first conductivity type semiconductor layer 151 of the light-emitting layer 151 to 153, the ohmic contact layer 154-1 may be disposed at and around the peak P of the recess 158, the reflective layer 154-2 may be disposed not only under the second region 150b of the light-emitting layer 151 to 153 but also on the slope surface 158-1 of the recess 158 or under the ohmic contact layer 154-1, and the magnetic layer 154-3 may be disposed under the reflective layer 154-2. By the structural change as described above, not only the shortest current paths may be formed, but also the arrangement area of the reflective layer 154-2 can be maximized, so that the light efficiency or luminance can be significantly improved. Accordingly, by providing the semiconductor light-emitting element 150-1 having the structure described above in the display device 302 according to the third embodiment, the contrast ratio can be increased and the image quality can be improved.

Meanwhile, even if the depth d4 of the recess 158 is very large, and the reflective layer 154-2 and the magnetic layer 154-3 are disposed in the recess 158, the second insulating layer 335 having a very large depth corresponding to the recess 158 may be formed in the recess 154-3a of the magnetic layer 154-3 formed on the lower side of the light-emitting layer 151 to 153. In this instance, since the second insulating layer 335 is disposed not only between the lower side of the semiconductor light-emitting element 150-1 and the first insulating layer 330, but also in the recess 154-3a of the magnetic layer 154-3, the fixation of the semiconductor light-emitting element 150-1 can be further strengthened by the second insulating layer 335.

### Sixth Embodiment

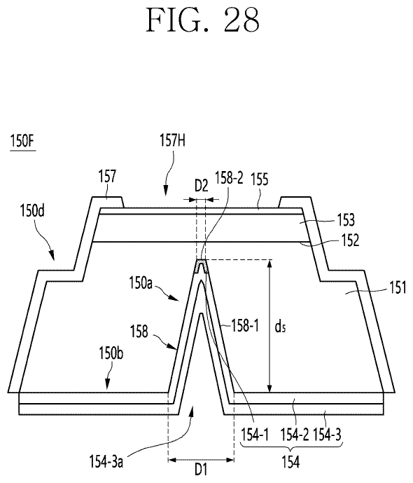

FIG. 28 is a cross-sectional view illustrating a semiconductor light-emitting element according to a sixth embodiment.

The sixth embodiment is the same as the fifth embodiment except for the shape of the recess 158. In the sixth embodiment, components having the same shape, structure, and/or function as those in the fifth embodiment are given the same drawing reference numerals, and detailed descriptions thereof are omitted.

Referring to FIG. 27, the semiconductor light-emitting element 150F according to the sixth embodiment may comprise a light-emitting layer 151 to 153, a passivation layer 157, a first electrode 154, and a second electrode 155. The semiconductor light-emitting element 150F according to the sixth embodiment may be a red semiconductor light-emitting element 150-1. The green semiconductor light-emitting element 150-2 or the blue semiconductor light-emitting element 150-3 may also have the same structure as the semiconductor light-emitting element 150F according to the sixth embodiment, except that the materials of the light-emitting layer 151 to 153 are different.

A recess 158 may be formed in the lower side of the first region 150a of the light-emitting layer 151 to 153. The recess 158 may have a cylindrical shape with a very deep depth d5 but with a diameter that becomes smaller as it goes upward. The recess 158 may have a slope surface 158-1 and a bottom surface 158-2. In this instance, the diameter D2 of the bottom surface 158-2 of the recess 158 may be less than or equal to ⅓ of the diameter D1 of the lowermost side of the recess 158.

The depth d5 of the recess 158 may be defined as a distance between the bottom surface 158-2 of the recess 158 and the lower surface of the second region 150b of the light-emitting layer 151 to 153. For example, the depth d5 of the recess 158 may be equal to or greater than ½ of the thickness of the first conductivity type semiconductor layer 151 of the light-emitting layer 151 to 153. For example, the bottom surface 158-2 of the recess 158 may be positioned higher than the step region in the multi-stage structure 150d. The bottom surface 158-2 of the recess 158 may be adjacent to the active layer 152, but may not be in contact with the active layer 152. The recess 158 may have a slope surface 158-1. As the depth d5 increases, the length or area of the slope surface 158-1 may increase.

The first electrode 154 may be disposed on the lower side of the light-emitting layer 151 to 153, and the second electrode 155 may be disposed on the upper side of the light-emitting layer 151 to 153. The first electrode 154 may comprise an ohmic contact layer 154-1, a reflective layer 154-2, and a magnetic layer 154-3. Although not illustrated, the first electrode 154 may comprise more layers than these.

An ohmic contact layer 154-1, a reflective layer 154-2, and a magnetic layer 154-3 may be disposed in the recess 158. The ohmic contact layer 154-1 may be disposed on the bottom surface 158-2 of the recess 158. Since the ohmic contact layer 154-1 is disposed on the bottom surface 158-2 of the recess 158, the ohmic contact layer 154-1 may be disposed very adjacent to the active layer 152. Accordingly, as described above, when a driving current flows in the semiconductor light-emitting element 150F, shortest currents paths may be formed between the second electrode 155 and the ohmic contact layer 154-1 with the active layer 152 interposed therebetween, so that more light may be generated in the active layer 152. In addition, the reflective layer 154-2 may be disposed not only under the second region 150b of the light-emitting layer 151 to 153, but also on the slope surface 158-1 of the recess 158, whose area increases as the depth d5 of the recess 158 increases, so that the light reflectance can be increased. In this way, the structure of the lower layer of the semiconductor light-emitting element 150F is changed so that the shortest current paths may be formed and the light reflectance is increased. Thus, the light efficiency and the light luminance can be significantly improved.

### Seventh Embodiment

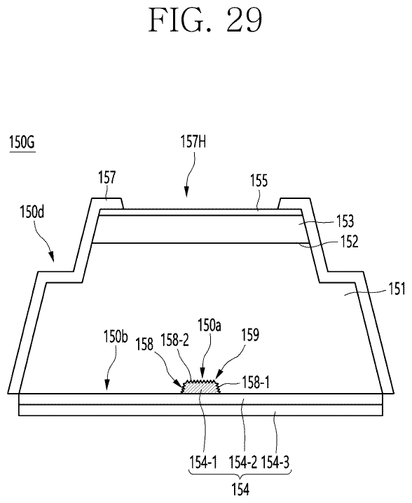

FIG. 29 is a cross-sectional view illustrating a semiconductor light-emitting element according to a seventh embodiment.

The seventh embodiment is the same as the first to sixth embodiments except for the unevenness 159 formed in the recess 158. In the seventh embodiment, components having the same shape, structure, and/or function as those of the first to sixth embodiments are given the same drawing reference numerals, and detailed descriptions thereof are omitted.

Referring to FIG. 29, the semiconductor light-emitting element 150G according to the seventh embodiment may comprise a light-emitting layer 151 to 153, a passivation layer 157, a first electrode 154, and a second electrode 155. The semiconductor light-emitting element 150G according to the seventh embodiment may be a red semiconductor light-emitting element 150-1. The green semiconductor light-emitting element 150-2 or the blue semiconductor light-emitting element 150-3 may also have the same structure as the semiconductor light-emitting element 150G according to the seventh embodiment, except that the materials of the light-emitting layer 151 to 153 are different.

A recess 158 may be formed in the lower side of the first region 150a of the light-emitting layer 151 to 153. An unevenness 159 may be formed on the inner surface of the recess 158. The unevenness 159 may be formed on the slope surface 158-1 of the recess 158. The unevenness 159 may be formed on the bottom surface 158-2 of the recess 158. By performing an additional etching process after the recess 158 is first formed, the unevenness 159 may be formed on the surface of the recess 158. The roughness of the unevenness 159 may be 50 Å or less.

The first electrode 154 may be disposed on the lower side of the light-emitting layer 151 to 153, and the second electrode 155 may be disposed on the upper side of the light-emitting layer 151 to 153. The first electrode 154 may comprise an ohmic contact layer 154-1, a reflective layer 154-2, and a magnetic layer 154-3. Although not illustrated, the first electrode 154 may comprise more layers than these.

An ohmic contact layer 154-1, a reflective layer 154-2, and a magnetic layer 154-3 may be disposed in the recess 158. The ohmic contact layer 154-1 may be disposed on the unevenness 159. The ohmic contact layer 154-1 may be disposed on the unevenness 159 formed on the slope surface 158-1 of the recess 158. The ohmic contact layer 154-1 may be disposed on the unevenness 159 formed on the bottom surface 158-2 of the recess 158. The thickness of the ohmic contact layer 154-1 may be the same as the depth of the recess 158, but is not limited thereto.

The reflective layer 154-2 may be disposed not only under the second region 150b of the light-emitting layer 151 to 153, but also under the ohmic contact layer 154-1. The magnetic layer 154-3 may be disposed under the reflective layer 154-2.

According to the seventh embodiment, the ohmic contact layer 154-1 may be disposed on the unevenness 159 formed in the recess 158. As described above, when heat treatment is performed to form the ohmic contact layer 154-1, the light reflectivity of the ohmic contact layer 154-1 decreases. However, since the unevenness 159 is formed in contact with the ohmic contact layer 154-1 disposed in the recess 158, the light that has traveled from the active layer 152 to the ohmic contact layer 154-1 is diffusely reflected or scattered by the unevenness 159 and does not enter the ohmic contact layer 154-1, so that the reduction in light reflection by the ohmic contact layer 154-1 can be prevented. In addition, since the light scattered or reflected by the unevenness 159 contributes to the light extraction effect, the light efficiency or luminance can be improved.

### Eighth Embodiment

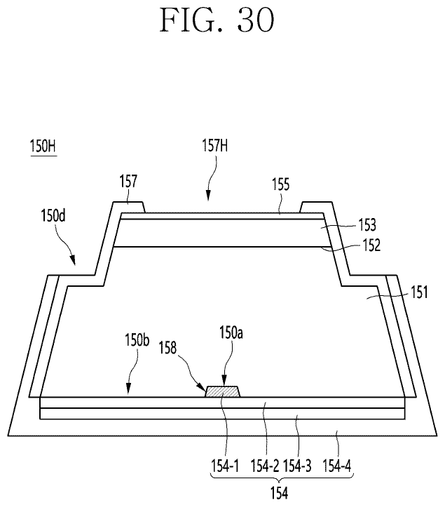

FIG. 30 is a cross-sectional view illustrating a semiconductor light-emitting element according to an eighth embodiment.

The eighth embodiment is the same as the first to seventh embodiments except for a contact electrode 154-4 included in the first electrode 154. In the eighth embodiment, the same components as in the first to seventh embodiments are given the same drawing reference numerals, and detailed descriptions thereof are omitted.

Referring to FIG. 30, the semiconductor light-emitting element 150H according to the eighth embodiment may comprise a light-emitting layer 151 to 153, a passivation layer 157, a first electrode 154, and a second electrode 155. The semiconductor light-emitting element 150H according to the eighth embodiment may be a red semiconductor light-emitting element 150-1. The green semiconductor light-emitting element 150-2 or the blue semiconductor light-emitting element 150-3 may also have the same structure as the semiconductor light-emitting element 150H according to the eighth embodiment, except that the materials of the light-emitting layer 151 to 153 are different.

A recess 158 may be formed in the lower side of the first region 150a of the light-emitting layer 151 to 153.

The first electrode 154 may be disposed on the lower side of the light-emitting layer 151 to 153, and the second electrode 155 may be disposed on the upper side of the light-emitting layer 151 to 153. The first electrode 154 may comprise an ohmic contact layer 154-1, a reflective layer 154-2, a magnetic layer 154-3, and a contact electrode 154-4. Although not illustrated, the first electrode 154 may comprise more layers than these.

The ohmic contact layer 154-1 may be disposed in the recess 158. A reflective layer 154-2 may be disposed under the second region 150b of the light-emitting layer 151 to 153, a magnetic layer 154-3 may be disposed under the reflective layer 154-2, and a contact electrode 154-4 may be disposed under the magnetic layer 154-3. The reflective layer 154-2, the magnetic layer 154-3, and the contact electrode 154-4 may be disposed under the ohmic contact layer 154-1.

The contact electrode 154-4 may be made of a metal having excellent contact characteristics. For example, the contact electrode 154-4 may have a multilayer structure such as Mo/Al/Mo.

In an embodiment, the contact electrode 154-4 may be disposed on a lateral part of the light-emitting layer 151 to 153. According to the eighth embodiment of the present invention, a semiconductor light-emitting element 150H having such a structure may be assembled into an assembly hole 340H of a backplane substrate (300A of FIG. 18) using a self-assembly process, and then a connecting electrode 370 may be formed. In this instance, when the connecting electrode 370 is formed along the perimeter of a lateral part the semiconductor light-emitting element 150H within the assembly hole 340H, the contact area between the contact electrode 154-4 and the connecting electrode 370 disposed on the lateral part of the light-emitting layer 151 to 153 can be expanded, so that electrical characteristics can be improved, thereby improving light efficiency and luminance, and low-voltage operation is possible, thereby reducing power consumption.

Although not illustrated, a reflective layer 154-2 and/or a magnetic layer 154-3 may also be disposed on the lateral part of the light-emitting layer 151 to 153.

### Ninth Embodiment

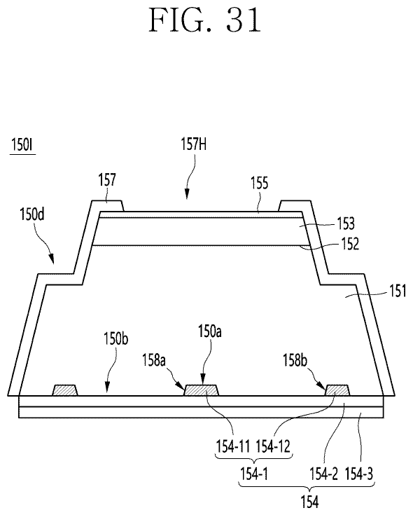

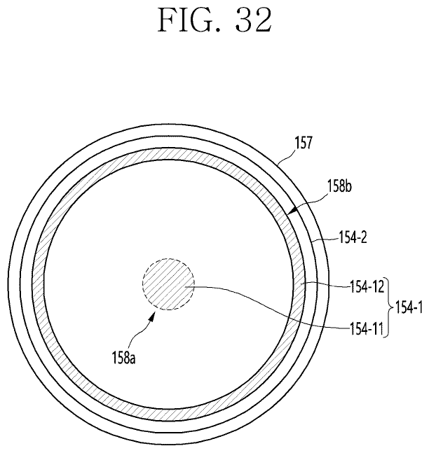

FIG. 31 is a cross-sectional view illustrating a semiconductor light-emitting element according to a ninth embodiment. FIG. 32 is a bottom view illustrating a semiconductor light-emitting element according to the ninth embodiment.

The ninth embodiment is the same as the first to seventh embodiments except that the ohmic contact layer 154-1 of the first electrode 154 may be locally disposed under the second region 150b of the light-emitting layer 151 to 153.

Referring to FIGS. 31 and 32, the semiconductor light-emitting element 150I according to the ninth embodiment may comprise the light-emitting layer 151 to 153, the passivation layer 157, the first electrode 154, and the second electrode 155. The semiconductor light-emitting element 150I according to the ninth embodiment may be a red semiconductor light-emitting element 150-1. The green semiconductor light-emitting element 150-2 or the blue semiconductor light-emitting element 150-3 may also have the same structure as the semiconductor light-emitting element 150I according to the ninth embodiment, except that the materials of the light-emitting layer 151 to 153 are different.

A first recess 158a may be formed in the lower side of the first region 150a of the light-emitting layer 151 to 153. The first recess 158a may have a shape corresponding to the shape of the first region 150a. The first recess 158a may have the same size as the size of the first region 150a of the light-emitting layer 151 to 153.

At least one second recess 158b may be formed on the lower side of the second region 150b of the light-emitting layer 151 to 153. The second recess 158b may be locally formed in the lower side of the second region 150b of the light-emitting layer 151 to 153. The second recess 158b may have a size smaller than the size of the second region 150b of the light-emitting layer 151 to 153. The second recess 158b may have a closed-loop ring shape. Although not illustrated, the second recess 158b may have a ring shape, but may also be formed of sub-recesses spaced apart from each other. The width of the second recess 158b may be smaller than the diameter of the first recess 158a, but is not limited thereto.

The first electrode 154 may be disposed on the lower side of the light-emitting layer 151 to 153, and the second electrode 155 may be disposed on the upper side of the light-emitting layer 151 to 153. The first electrode 154 may comprise an ohmic contact layer 154-1, a reflective layer 154-2, a magnetic layer 154-3, and a contact electrode 154-4. Although not illustrated, the first electrode 154 may comprise more layers.

The ohmic contact layer 154-1 may comprise a first ohmic contact layer 154-11 disposed in the first recess 158a and a second ohmic contact layer 154-12 disposed in at least one second recess 158b. The first ohmic contact layer 154-11 may have a shape corresponding to a shape of the first recess 158a. The second ohmic contact layer 154-12 may have a shape corresponding to a shape of the second recess 158b. The width of the second ohmic contact layer 154-12 disposed in the second recess 158b may be smaller than the diameter of the first ohmic contact layer 154-11 disposed in the first recess 158a, but is not limited thereto.

The reflective layer 154-2 may be disposed on the lower side of the light-emitting layer 151 to 153. The reflective layer 154-2 may be disposed on the lower side of each of the first region 150a and the second region 150b of the light-emitting layer 151 to 153. The reflective layer 154-2 may surround the first ohmic contact layer 154-11 and/or the second ohmic contact layer 154-12. The reflective layer 154-2 may be in contact with the remaining lower surface except for the lower surface of the second region 150b of the light-emitting layers 151 to 153 to which the second ohmic contact layer 154-12 is in contact. The magnetic layer 154-3 may be disposed under the reflective layer 154-2.

According to the ninth embodiment, the ohmic contact layer 154-1 may be locally disposed not only under the first region 150a of the light-emitting layer 151 to 153 but also on the lower surface of the second region 150b of the light-emitting layer 151 to 153, so that in addition to improving the electrical characteristics by the ohmic contact layer 154-1, the light efficiency and luminance can be improved by increasing the light reflectivity by the reflective layer 154-2.

Meanwhile, the display device described above may be a display panel. That is, in the embodiment, the display device and the display panel may be understood to have the same meaning. In the embodiment, the display device in the practical sense may comprise a display panel and a controller (or processor) that may control the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment may be adopted in the display field for displaying images or information. The embodiment may be adopted in the display field for displaying images or information using a semiconductor light-emitting element. The semiconductor light-emitting element may be a micro-level semiconductor light-emitting element or a nano-level semiconductor light-emitting element.

For example, the embodiment may be adopted in a TV, signage, a mobile terminal such as a mobile phone or a smart phone, display for computers such as laptop or desktop, a head-up display (HUD) for an automobile, a backlight unit for display, display for VR, AR or mixed reality (MR), a light source, etc.

1. A semiconductor light-emitting element, comprising:
a light-emitting layer;
a passivation layer configured to surround a lateral part of the light-emitting layer;
a first electrode under the light-emitting layer; and
a second electrode on the light-emitting layer;
wherein the light-emitting layer has a first region and a second region configured to surround the first region and a lower surface of the first region of the light-emitting layer has a recess,
wherein the first electrode comprises:
an ohmic contact layer in the recess;
a reflective layer under the second region of the light-emitting layer; and
a magnetic layer under the reflective layer, and
wherein an area of the reflective layer is configured to exceed 50% of an area of a lower side of the light-emitting layer.

2. The semiconductor light-emitting element of claim 1, wherein an area of the ohmic contact layer is 5% to 50% of the area of the lower side of the light-emitting layer.

3. The semiconductor light-emitting element of claim 1, wherein the reflective layer is disposed under the ohmic contact layer.

4. The semiconductor light-emitting element of claim 3, wherein the reflective layer comprises a protrusion configured to surround the ohmic contact layer in the recess.

5. The semiconductor light-emitting element of claim 1, wherein a lower surface of the ohmic contact layer and a lower surface of the second region of the light-emitting layer are positioned on a same horizontal line.

6. The semiconductor light-emitting element of claim 1, wherein a lower surface of the ohmic contact layer is positioned higher than a lower surface of the second region of the light-emitting layer.

7. The semiconductor light-emitting element of claim 6, wherein the magnetic layer has a second recess corresponding to the recess.

8. The semiconductor light-emitting element of claim 6, wherein the magnetic layer is disposed under the reflective layer, and a lower surface of the magnetic layer has a straight plane.

9. The semiconductor light-emitting element of claim 1, wherein a lower surface of the ohmic contact layer is positioned lower than a lower surface of the second region of the light-emitting layer.

10. The semiconductor light-emitting element of claim 9, wherein the magnetic layer is disposed under the reflective layer, and a lower surface of the magnetic layer has a straight plane.

11. The semiconductor light-emitting element of claim 1, wherein the recess has a depth of ½ or more of a thickness of a first conductivity type semiconductor layer of the light-emitting layer.

12. The semiconductor light-emitting element of claim 11, wherein the recess has a bottom surface and a slope surface,
wherein the ohmic contact layer is disposed on the bottom surface, and
wherein the reflective layer is disposed on the slope surface.

13. The semiconductor light-emitting element of claim 1, comprising:
an unevenness on the surface of the recess,
wherein the ohmic contact layer is disposed on the unevenness.

14. The semiconductor light-emitting element of claim 1, wherein the first electrode comprises a contact electrode under the magnetic layer.

15. The semiconductor light-emitting element of claim 14, wherein at least one of the reflective layer, the magnetic layer, or the contact electrode is disposed on the lateral part of the light-emitting layer.

16. A display device, comprising:
a backplane substrate;
a plurality of semiconductor light-emitting elements configured to emit light of different colors on the backplane substrate;
a connecting electrode on each lateral part of the plurality of semiconductor light-emitting elements; and
an electrode wiring on each upper side of the plurality of semiconductor light-emitting elements,
wherein at least one or more of the plurality of semiconductor light-emitting elements comprises:
a light-emitting layer;
a passivation layer configured to surround a lateral part of the light-emitting layer;
a first electrode under the light-emitting layer; and
a second electrode over the light-emitting layer,
wherein the light-emitting layer has a first region and a second region configured to surround the first region and a lower surface of the first region of the light-emitting layer has a recess, and
wherein the first electrode comprises:
an ohmic contact layer in the recess;
a reflective layer under the second region of the light-emitting layer; and
a magnetic layer under the reflective layer.
